(19) United States
(12) Patent Application Publication
(10) Pub. No.: US 2025/0151257 A1
(43) Pub. Date: May 8, 2025

(54) SEMICONDUCTOR DEVICES AND FABRICATION METHODS THEREOF, AND MEMORY SYSTEMS

(71) Applicant: Yangtze Memory Technologies Co., Ltd., Wuhan (CN)

(72) Inventors: Dongmen Song, Wuhan (CN); Mingliang Xu, Wuhan (CN); Zhaoyun Tang, Wuhan (CN); He Chen, Wuhan (CN); WenYu Hua, Wuhan (CN); FanDong Liu, Wuhan (CN); Wenxiang Xu, Wuhan (CN); Ya Wang, Wuhan (CN); Zijin Yang, Wuhan (CN); ZongLiang Huo, Wuhan (CN)

(21) Appl. No.: 18/663,925

(22) Filed: May 14, 2024

(30) Foreign Application Priority Data
Nov. 2, 2023 (CN) 202311461867.2

(51) Int. Cl. H10B 12/00

(52) U.S. Cl. CPC H10B 12/315; H10B 12/05

(57) ABSTRACT

Implementations of the present application provide a semiconductor device, a fabrication method and a memory system. The semiconductor device includes a plurality of semiconductor pillars arranged in an array and a word line structure. The plurality of semiconductor pillars extend along a first direction and include at least one side face, wherein the plurality of semiconductor pillars are arranged in rows along a second direction perpendicular to the first direction. The word line structure is located between a first row and a second row of semiconductor pillars that are adjacent, and includes a first word line structure and a second word line structure spaced apart from the first word line structure, wherein the first word line structure is connected with a side face of the first row of semiconductor pillars, and the second word line structure is connected with a side face of the second row of semiconductor pillars.

### CROSS-REFERENCE TO RELATED APPLICATIONS

The present application claims the benefit of priority to China Application No. 202311461867.2, filed on Nov. 2, 2023, the content of which is incorporated herein by reference in its entirety.

### TECHNICAL FIELD

The present application relates to the field of semiconductor design and fabrication, and particularly to semiconductor devices, fabrication methods of the semiconductor devices and memory systems.

### BACKGROUND

A dynamic random access memory (DRAM) is one of the important memory components in an electronic system. Taking the DRAM as an example, a semiconductor device may comprise memory cells composed of capacitors and transistors, wherein a plurality of memory cells may be arranged in a form of a two-dimensional array. Furthermore, in order to further reduce a size of the two-dimensional array, the transistor may comprise a vertical gate transistor (VGT). In such a structure, a source and a drain of the transistor are formed at two ends of a channel of the transistor respectively in an extending direction, and a gate structure of the transistor is formed on at least one side of the channel.

### BRIEF DESCRIPTION OF THE DRAWINGS

Other features, purposes and advantages of the present application will become more apparent by reading the detailed description of non-limitative implementations made with reference to the following drawings. Among the drawings:

FIG. 1 is a top perspective view of a semiconductor device according to example implementations of the present application;

FIG. 2 is a cross-sectional view of a semiconductor device shown in FIG. 1 taken along a line A-A′;

FIG. 3 is a cross-sectional view of a semiconductor device shown in FIG. 1 taken along a line B-B′;

FIG. 4 is a cross-sectional view of a semiconductor device shown in FIG. 1 taken along a line C-C′;

FIG. 5 is a cross-sectional view of a semiconductor device shown in FIG. 1 taken along a line D-D′;

FIG. 6 is a flow diagram of a method of fabricating a semiconductor device according to example implementations of the present application;

FIGS. 7-39 are respective process diagrams of a fabrication method of a semiconductor device according to one implementation of the present application; and

FIG. 40 is a schematic structural diagram of a memory system according to one implementation of the present application.

### DETAILED DESCRIPTION

In order to better understand the present application, various aspects of the present application will be described in more detail with reference to the drawings. It is understood that, these detailed descriptions are only descriptions of example implementations of the present application, and are not intended to limit the scope of the present application in any manner. Like reference numbers denote like elements throughout the specification. The expression “and/or” includes any or all combinations of one or more of listed associated items.

It is to be noted that, in the specification, the expressions such as first, second, third and the like, are only used to distinguish one feature from another feature, instead of representing any limitation to the features, particularly instead of representing any sequential order. Thus, without departing from the teaching of the present application, a first word line structure discussed in the present application may be also called a second word line structure, and vice versa.

For ease of illustration, the thicknesses, sizes and shapes of components have been slightly adjusted in the drawings. The drawings are merely examples and are not drawn to scale precisely. As used herein, terms “approximately”, “about”, and the like, are used to represent approximation, instead of representing degrees, and are intended to describe inherent deviations in measured values or calculated values as recognized by those of ordinary skill in the art.

It should be also understood that, expressions, such as “comprise”, “comprising”, “have”, “include”, and/or “including”, etc., are open-ended expressions, rather than close-ended expressions in the specification. They represent the existence of the stated features, elements and/or components, but do not exclude the existence of one or more other features, elements, components and/or combinations thereof. Moreover, the expression, such as “at least one of . . . ”, appearing before a list of listed features, modifies the whole list of features, rather than an individual element therein. Furthermore, the term “may” is used to represent “one or more implementations of the present application” when describing the implementations of the present application. Moreover, the term “exemplary” is intended to refer to an example or illustration.

Unless otherwise defined, all phraseologies (including engineering terms and technical terms) as used herein have the same meanings as those generally understood by those of ordinary skill in the art to which the present application pertains. It should be further understood that, terms as defined in common dictionaries should be interpreted as having meanings that are consistent with their meanings in the context of the related art, and should not be interpreted in an idealized or overly formal sense unless otherwise stated expressly in the present application.

It is to be noted that, implementations and features in the implementations of the present application may be mutually combined in the case of no conflicts. In addition, unless otherwise defined expressly or conflicting with the context, specific steps included in a method as set forth in the present application are not necessarily limited to the described order, but may be carried out in any order or in parallel.

Furthermore, “connected” or “joined”, when used in the present application, may represent direct contact or indirect contact between respective components, unless otherwise expressly defined or derived from the context.

The present application will be detailed below by reference to the drawings and in conjunction with the implementations.

With rapid development of semiconductor technology, how to optimize the overall performance of the semiconductor device, simplify the fabrication process and reduce the process cost is one of the important research directions in the industry.

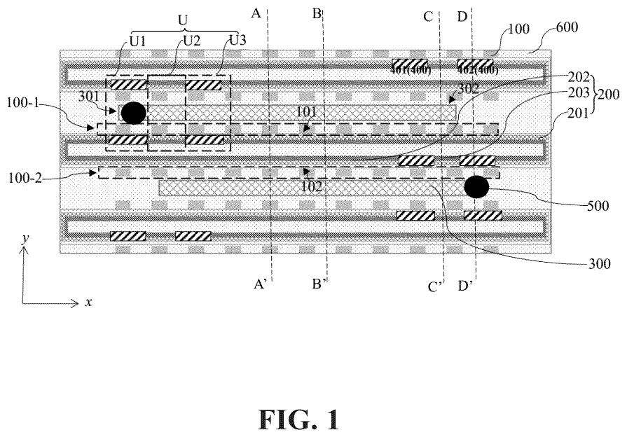

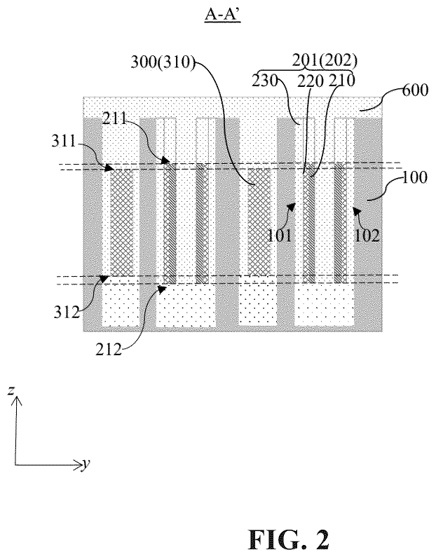

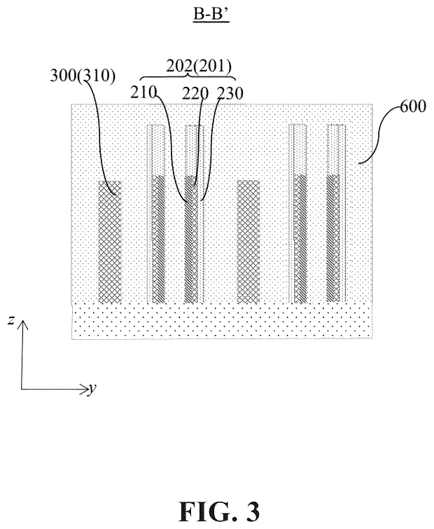

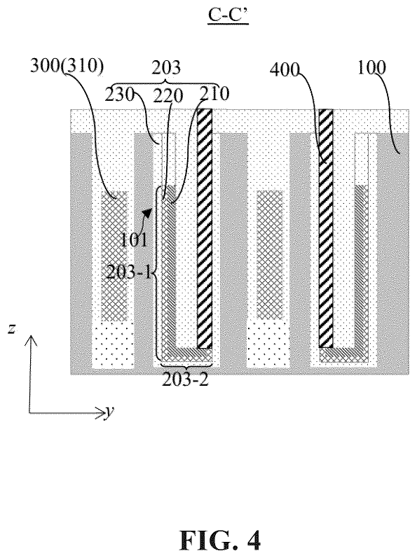

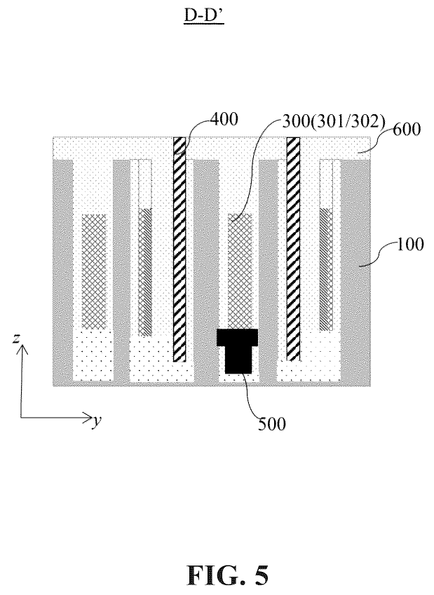

Some implementations of the present application provide a semiconductor device. FIG. 1 is a top perspective view of a semiconductor device 1000 according to example implementations of the present application. FIG. 2 is a cross-sectional view of the semiconductor device 1000 shown in FIG. 1 taken along a line A-A′. FIG. 3 is a cross-sectional view of the semiconductor device 1000 shown in FIG. 1 taken along a line B-B′. FIG. 4 is a cross-sectional view of the semiconductor device 1000 shown in FIG. 1 taken along a line C-C′. FIG. 5 is a cross-sectional view of the semiconductor device 1000 shown in FIG. 1 taken along a line D-D′.

As shown in FIGS. 1-5, the semiconductor device 1000 may comprise semiconductor pillars 100 and a word line structure 200. A plurality of semiconductor pillars 100 extend along a first direction (the z direction) and comprise at least one side face, for example, a first side face 101, a second side face 102, etc. The plurality of semiconductor pillars 100 are arranged in rows along a second direction (an x direction) perpendicular to the first direction to form a plurality of rows of semiconductor pillars, for example, a first row of semiconductor pillars 100-1, a second row of semiconductor pillars 100-2, etc. The word line structure 200 is located between the first row of semiconductor pillars 100-1 and the second row of semiconductor pillars 100-2 that are adjacent to each other. The word line structure 200 may comprise a first word line structure 201 and a second word line structure 202 spaced apart from the first word line structure 201, wherein the first word line structure 201 is connected with a side face of the first row of semiconductor pillars 100-1, for example, the first word line structure 201 is connected with the first side face 101 of the plurality of semiconductor pillars 100 in the first row of semiconductor pillars 100-1; and the second word line structure 202 is connected with a side face of the second row of semiconductor pillars 100-2, for example, the second word line structure 202 is connected with the second side face 102 of the plurality of semiconductor pillars 100 in the second row of semiconductor pillars 100-2.

According to the semiconductor device provided by at least one implementation of the present application, the semiconductor device may comprise the word line structure and a plurality of semiconductor pillars arranged in an array, wherein the plurality of semiconductor pillars are arranged in rows to form rows of semiconductor pillars, the word line structure is disposed between the adjacent rows of semiconductor pillars and comprises the first word line structure and the second word line structure spaced apart from each other, and the adjacent rows of semiconductor pillars are connected with one of the first word line structure and the second word line structure respectively. Since sub-word line structures (which may be understood as the first word line structure and the second word line structure) connecting the adjacent rows of semiconductor pillars are spaced from each other, occurrences of short circuit between the sub-word line structures may be reduced, and the electrical performance of the semiconductor device can be improved.

In some related technologies, after forming a trench accommodating the word line structure, it is difficult to form a flat surface at the bottom of the trench due to limitations of an etching process. Therefore, filling (e.g., an FCVD process) and multiple times of back etching are required to be performed on the bottom of the trench to construct a trench with a flat bottom face. After the formation of the trench with the flat bottom face, an initial word line structure may be formed on sidewalls and the bottom face of the trench. Subsequently, a portion of the initial word line structure at the bottom face of the trench is removed from a front side of an intermediate structure using a process such as punch etching, etc., to break the initial word line structure apart into two word line structures on the opposite sidewalls of the trench. However, in the above process, in an operation of performing filling and multiple times of back-etching on the trench, the process cost is high and the control is difficult. In addition, in an operation of removing the portion of the initial word line structure at the bottom face of the trench using, for example, punch etching, the process window is small, and it is difficult to completely break the initial word line structure apart at the bottom of the trench, which may cause a short circuit to occur at an electrical connection of the two word line structures and affect the electrical performance of the final semiconductor device.

In order to at least partially solve the above technical problem, according to at least one implementation of the present application, the word line structure is disposed between the adjacent rows of semiconductor pillars, and comprises sub-word line structures spaced apart from each other, and the adjacent rows of semiconductor pillars are connected with one of the sub-word line structures respectively. Since the sub-word line structures connected with the adjacent rows of semiconductor pillars are spaced from each other, occurrences of short circuit between the sub-word line structures may be reduced, and the electrical performance of the semiconductor device can be improved.

In an example, by taking the dynamic random access memory as an example, the semiconductor device may comprise a plurality of memory cells composed of capacitors and transistors, wherein the plurality of memory cells may be arranged in a form of a two-dimensional array. In order to further reduce a size of the two-dimensional array, the transistor may comprise a vertical gate transistor. In such a structure, an extending direction of a channel of the transistor is perpendicular to a surface of a substrate, and a source and a drain may be respectively formed at two ends in the extending direction, and a gate structure of the transistor may be formed on a side of the channel.

In one implementation of the present application, a vertical transistor such as a vertical Metal-Oxide-Semiconductor Field-Effect Transistor (MOSFET), etc. may replace a conventional planar transistor as a pass transistor of the memory cell to reduce the footprint, coupling capacitance and interconnect routing complexity of the pass transistor. In some implementations, different from the planar transistor with an active area formed in the substrate, the vertical transistor may comprise the semiconductor pillar 100 extending vertically above the substrate (not shown) along the z direction. The semiconductor pillar 100 may extend above a top surface of the substrate, not only exposing a top surface of the semiconductor pillar 100, but also exposing one or more side faces of the semiconductor pillar 100, for example, the first side face 101 and the second side face 102.

In an example, a cross-sectional shape of the semiconductor pillar 100 in a plane (e.g., an x-y plane, wherein the x direction, y direction and z direction are perpendicular to one another) perpendicular to the z direction may comprise at least one of a rectangular shape, a trapezoidal shape, a circular shape or an oval shape. For example, a shape of the semiconductor pillar 100 may be a hexahedral shape, and comprise four side faces.

In other words, the semiconductor pillar 100 may have a cubic shape to expose four side faces thereof. However, it is understood by those skilled in the art that the semiconductor pillar 100 may have any suitable three-dimensional shape, for example, a polyhedron shape or a cylinder shape. A cross-section of the semiconductor pillar 100 in the plane perpendicular to the z direction may have a square shape, a rectangular shape, a trapezoidal shape, a circular shape, an oval shape or any other suitable shape. It is to be understood that, consistent with the scope of the present application, for the semiconductor pillar having the cross-section of the circular shape or the oval shape in the above-mentioned plane, the semiconductor pillar may be still considered as having a plurality of side faces, such that the gate structure is in contact with one of the side faces of the semiconductor pillar. As described below with respect to the fabrication process, the semiconductor pillar 100 may be formed from the substrate by, for example, an etching or epitaxial process, and thus may have the same semiconductor material as the substrate.

As an alternative, a material of the substrate may include, but is not limited to, silicon (e.g., monocrystalline silicon c-Si), silicon germanium (SiGe), gallium arsenide (GaAs), germanium (Ge), silicon on insulator (SOI) or any other suitable semiconductor materials. For example, the substrate may be a silicon substrate. Accordingly, the semiconductor pillar 100 may comprise at least one of the above-mentioned materials.

The vertical transistor may comprise a gate structure in contact with one side face (e.g., the first side face 101 or the second side face 102) of the semiconductor pillar 100. It may be understood that the gate structure and the word line structure 200 may be a continuous conductive structure, and the gate structure may be regarded as an extension of the word line structure 200 to couple to the semiconductor pillar 100; or the word line structure 200 may be regarded as an extension of the gate structure to couple to a peripheral circuit (not shown).

For example, in the case where the semiconductor pillar 100 comprises four side faces, the first side face 101 and the second side face 102 are two opposite side faces of the semiconductor pillar 100 in the y direction, and the word line structure 200 (which may be also understood as the gate structure) may be located on the first side face 101 or the second side face 102.

In some implementations, the vertical transistor may also comprise a source (not shown) and a drain (not shown) respectively formed at two ends of the semiconductor pillar 100 in the z direction, which may be understood as doped areas of the semiconductor pillar 100, and may be also called a source electrode and a drain electrode. It is to be noted that, the source may be disposed below the semiconductor pillar 100, and the drain may be disposed above the semiconductor pillar 100. However, according to actual needs, the source may be also disposed above the semiconductor pillar 100, and the drain may be disposed below the semiconductor pillar 100, which is not limited by the present application.

As an alternative, the source and the drain may be doped with any suitable P-type dopant that may comprise any one or a combination of boron (B) or gallium (Ga). As another alternative, the source and the drain may be doped with any suitable N-type dopant that may comprise any one or a combination of phosphorus (P), arsenic (As) and antimony (Sb). The source and the drain may be separated by the gate structure in the z direction. In other words, the gate structure is formed between the source and the drain along the z direction. Therefore, when a gate voltage applied to the gate structure is higher than a threshold voltage of the vertical transistor, the channel of the vertical transistor can be formed in the semiconductor pillar 100 between the source and the drain along the z direction (which may be understood as the gate control capability of the gate structure).

In one implementation of the present application, the word line structure 200 may comprise a word line dielectric layer 230 and a word line conductor layer, wherein the word line dielectric layer 230 is located between the semiconductor pillar 100 and the word line conductor layer. In an example, the word line conductor layer may further comprise a word line adhesion layer 220 and a word line metal layer 210.

For example, the word line structure 200 may comprise the word line dielectric layer 230 on the semiconductor pillar 100. Furthermore, the word line structure 200 may further comprise the word line adhesion layer 220 over the word line dielectric layer 230 and in contact with the word line dielectric layer 230, and the word line metal layer 210 over the word line adhesion layer 220 and in contact with the word line adhesion layer 220. In other words, the word line adhesion layer 220 is located between the word line dielectric layer 230 and the word line metal layer 210.

The word line dielectric layer 230 may comprise any suitable dielectric material, for example, silicon oxide, silicon nitride, silicon oxynitride or high-k dielectric. For example, the word line dielectric layer 230 may comprise silicon oxide. Furthermore, the word line adhesion layer 220 may include, but is not limited to, titanium, titanium nitride, tantalum, tantalum nitride, etc. Additionally, the word line metal layer 210 may comprise any suitable conductive material, for example, the word line metal layer 210 may include, but is not limited to, tungsten (W), cobalt (Co), copper (Cu), aluminum (Al), etc. The word line adhesion layer 220 may be used to block diffusion of metal materials in the word line metal layer 210, and may be also used to improve adhesion between the word line metal layer 210 and the word line dielectric layer 230.

In an example, as shown in FIGS. 1 and 2, the first word line structure 201 and the second word line structure 202 may extend on the side face of the semiconductor pillar 100 along the z direction respectively, and may each comprise an upper end face 211 and a lower end face 212 that are opposite in the z direction. A plurality of upper end faces 211 are flush in the z direction; and/or a plurality of lower end faces 212 are flush in the z direction.

In other words, according to at least one implementation of the present application, the semiconductor device 1000 comprises the first word line structure 201, the second word line structure 202 and the semiconductor pillars 100 arranged in an array, wherein the first word line structure 201 and the second word line structure 202 each comprises the lower end faces 212 close to bottom ends of the semiconductor pillars 100 and the upper end faces 211 close to top ends of the semiconductor pillars 100. In an example, the upper end faces 211 of the plurality of first word line structures 201 and the upper end faces 211 of the plurality of second word line structures 202 are flush relative to the same reference plane in the z direction. In an example, the lower end faces 212 of the plurality of first word line structures 201 and the lower end faces 212 of the plurality of second word line structures 202 are flush relative to the same reference plane in the z direction. In an example, the upper end faces 211 of the plurality of first word line structures 201 and the upper end faces 211 of the plurality of second word line structures 202 are flush relative to the same reference plane in the z direction, and the lower end faces 212 of the plurality of first word line structures 201 and the lower end faces 212 of the plurality of second word line structures 202 are flush relative to the same reference plane in the z direction. It is to be noted that, due to the limitation of the process, the error range relative to the same reference plane described above may be between −10% to 10%.

As described above, in some examples, after a trench for accommodating the word line structure is formed, it is usually difficult to form a flat plane at the bottom of the trench due to limitations of an etching process. Furthermore, since a shape of an initial word line structure formed previously tends to a formation state of a sidewall and a bottom face of the trench, the cross-sectional shape of the initial word line structure in the x-y plane is not regular, and extending lengths of the plurality of initial word line structures in the z direction are not consistent.

In order to at least partially solve the above technical problems, according to at least one implementation of the present application, the word line structure is formed by removing part of the initial word line structure from a backside opposite to a front side of an intermediate structure, and an uneven portion of the initial word line structure on the bottom face of the trench is removed, so that the cross-section of the finally formed word line structure in the x-y plane may be formed as a regular rectangular shape, and the extending lengths of the plurality of word line structures in the z direction can be the same. The contents related to a fabrication method of a semiconductor device will be described in detail below in conjunction with the drawings.

Thus, in at least one implementation of the present application, at least one of the upper end faces and the lower end faces of the different first word line structures and the different second word line structures is flush relative to the reference plane in the z direction. This can improve the consistency of the word line structure, enhance the gate control capability of the word line structure (which may be understood as the gate structure), and improve the switching speed of the word line structure and the reliability of the semiconductor device.

It may be understood that, the lower end faces of the plurality of first word line structures and the lower end faces of the plurality of second word line structures being flush relative to the same reference plane in the z direction may be understood as lower end faces of the word line conductor layers of the plurality of first word line structures and lower end faces of the word line conductor layers of the plurality of second word line structures being flush relative to the same reference plane in the z direction. The upper end faces of the plurality of first word line structures and the upper end faces of the plurality of second word line structures being flush relative to the same reference plane in the z direction may be understood as upper end faces of the word line conductor layers of the plurality of first word line structures and upper end faces of the word line conductor layers of the plurality of second word line structures being flush relative to the same reference plane in the z direction.

With reference to FIGS. 1-5, in one implementation of the present application, the word line structure 200 further comprises a third word line structure 203 disposed between the first word line structure 201 and the second word line structure 202 in the x direction. The third word line structure 203 may comprise a first sub-portion 203-1 and a second sub-portion 203-2 connected with each other, wherein the first sub-portion 203-1 extends on the side face of the semiconductor pillar 100 along the z direction, and the second sub-portion 203-2 extends along the y direction.

In an example, a cross-sectional shape of the third word line structure 203 in a plane (the y-z plane) perpendicular to the x direction comprises an L shape. As an alternative, the third word line structure 203 may be connected with a peripheral circuit (not shown) of the semiconductor device 1000, for example, with an electrode of the peripheral circuit through a vertical interconnect via (VIA).

It is to be noted that, the semiconductor pillar 100 comprises two ends that are opposite in the z direction, and the ends of the plurality of semiconductor pillars 100 in the z direction may be connected with each other through, for example, a bit line extending in the y direction. The word line dielectric layer 230 of the first word line structure 201 is located on the first side face 101 of the semiconductor pillar 100. The word line dielectric layer 230 of the second word line structure 202 is located on the second side face 102 of the semiconductor pillar 100. A word line dielectric layer 230 of the third word line structure 203 is located on the side face of the semiconductor pillar 100 and a surface of a portion where the adjacent semiconductor pillars 100 are connected with each other in the y direction.

In other words, the second sub-portion 203-2 of the third word line structure 203 extends along the y direction, and comprises the word line dielectric layer 230 and a word line conductor layer extending along the y direction, wherein the word line dielectric layer 230 and the word line conductor layer are sequentially formed on the surface of the portion where the adjacent semiconductor pillars 100 are connected with each other in the y direction.

Furthermore, with reference to FIGS. 1, 4 and 5, in one implementation of the present application, the semiconductor device 1000 further comprises an isolation structure 400. The isolation structure 400 is located between the first word line structure 201 and the third word line structure 203 in the x direction; and/or the isolation structure 400 is located between the second word line structure 202 and the third word line structure 203 in the x direction.

In other words, the isolation structure 400 may comprise a first isolation structure 401 and a second isolation structure 402. In an example, the semiconductor device 1000 may comprise the first isolation structure 401 that is located between the first word line structure 201 and the third word line structure 203 in the x direction. In an example, the semiconductor device 1000 may comprise the second isolation structure 402 that is located between the second word line structure 202 and the third word line structure 203 in the x direction. In an example, the semiconductor device 1000 may comprise the first isolation structure 401 and the second isolation structure 402, wherein the first isolation structure 401 is located between the first word line structure 201 and the third word line structure 203 in the x direction, and the second isolation structure 402 is located between the second word line structure 202 and the third word line structure 203 in the x direction.

In an example, the isolation structure 400 may comprise any suitable dielectric material, for example, silicon oxide, silicon nitride, silicon oxynitride or high-k dielectric. For example, the isolation structure 400 may comprise silicon oxide.

In an example, withe reference to FIGS. 1, 4 and 5, in one implementation of the present application, the isolation structure 400 extends along the z direction, and may be connected with the second sub-portion 203-2 of the third word line structure 203 in the x direction.

The third word line structure 203 and the isolation structure 400 may form an isolation region U completely separating the first word line structure 201 and the second word line structure 202 in the semiconductor device 1000, wherein the isolation region U may effectively separate the first word line structure 201 and the second word line structure 202, which effectively reduces occurrences of short circuit between the word line structures and enhances an effect of improving the electrical performance of the semiconductor device.

Furthermore, the isolation region U may further comprise three sub-regions sequentially arranged along the x direction, wherein the first sub-region U1 and the third sub-region U3 are located on two sides of the second sub-region U2, and the third word line structure 203 is disposed in the second sub-region U2. The isolation structure 400 may be disposed in at least one of the first sub-region U1 or the third sub-region U3. The first sub-region U1 is closer to an edge of the semiconductor device 1000 than the second sub-region U2 and the third sub-region U3.

Furthermore, in order to reduce interference between the adjacent word line structures 200 in the semiconductor device 1000, the semiconductor device 1000 further comprises a back gate structure 300 that extends along the x direction, and the back gate structure 300 and the word line structures 200 are distributed alternately in the y direction.

The back gate structure 300 may comprise a back gate dielectric layer on a sidewall of the semiconductor pillar 100, and a back gate conductive layer 310 over the back gate dielectric layer and in contact with the back gate dielectric layer. By applying a reference voltage (e.g., a ground voltage) to the back gate conductive layer 310, the interference between the adjacent word line structures 200 in the semiconductor device 1000 may be reduced.

In an example, the back gate dielectric layer may comprise any suitable dielectric material, for example, silicon oxide, silicon nitride, silicon oxynitride or high-k dielectric. For example, the back gate dielectric layer may comprise silicon oxide. Furthermore, the back gate conductive layer 310 may include, but is not limited to, titanium, titanium nitride, tantalum, tantalum nitride, etc.

In order to simplify the fabrication process and save the production cost, the back gate dielectric layer may be formed in a fabrication process of forming the word line dielectric layer 230, and the word line dielectric layer 230 and the back gate dielectric layer may be fabricated using the same material. In other words, the word line dielectric layer 230 and the back gate dielectric layer may comprise an insulation material layer fabricated by the same material.

Likewise, in order to simplify the fabrication process and save the production cost, the back gate conductive layer 310 and the word line adhesion layer 220 may be fabricated using the same material. In other words, the word line adhesion layer 220 and the back gate conductive layer 310 may comprise a conductive material layer of the same material.

Furthermore, in one implementation of the present application, the back gate structure 300 comprises two ends (a first end 301 and a second end 302) opposite in the x direction. The first end 301 and the second end 302 are disposed opposite to the isolation structure 400 on two sides of the semiconductor pillar 100 in the y direction. For example, FIG. 1 shows that in the first sub-region U1, the first end 301 and the first isolation structure 401 are oppositely disposed on two sides of the semiconductor pillar 100 in the y direction. The semiconductor device 1000 further comprise a ground structure 500 connected with the first end 301 or the second end 302 of the back gate structure 300. The ground structure 500 may provide a reference voltage, and the ground structure 500 is connected with the back gate conductive layer 310 of the back gate structure 300 at the first end 301 or the second end 302, which can reduce the interference between the adjacent word line structures 200 in the semiconductor device 1000.

In an example, with reference to FIGS. 1 and 5, the first end 301 or the second end 302 of the back gate structure 300 are disposed above the ground structure 500 along the z direction.

Since the back gate structure extends along the x direction and are distributed alternately with the word line structures in the y direction, in some related technologies, a lead-out line of the back gate structure (the lead-out line may be connected to the reference voltage) and a lead-out line of the word line structure are distributed alternately in the y direction as well, which will result in a small process window for both lead-out lines. If both lead-out lines are connected together accidentally, a short circuit will occur, which may affect the overall performance of the final semiconductor device.

In order to at least partially solve the above technical problem, according to at least one implementation of the present application, the ground structure is disposed within the isolation region, and is connected with the end of the back gate structure extending into the isolation region. On this basis, the end of the back gate structure is disposed opposite to the isolation structure on the two sides of the semiconductor pillar in the y direction. In other words, the end of the back gate structure is not adjacent to the first word line structure or the second word line structure. As such, the lead-out line of the first word line structure or the second word line structure and the lead-out line of the back gate structure are located in different portions in the x-y plane respectively. The process windows of both lead-out lines are enlarged. In addition, the possibility of accidental connection of both lead-out lines is reduced, and the overall performance of the semiconductor device is improved.

In addition, as shown in FIGS. 1-5, in one implementation of the present application, the word line structure 200 and the back gate structure 300 may be located on two sides of the semiconductor pillar 100 that are opposite in the y direction. For example, the word line structure 200 is located on the first side face 101 of the semiconductor pillar 100, and the back gate structure 300 is located on the second side face 102 of the semiconductor pillar 100.

In an example, as shown in FIGS. 1 and 2, the back gate structure 300 extends on the side face of the semiconductor pillar 100 along the z direction, and comprises top end faces 311 and bottom end faces 312 that are opposite in the z direction. The plurality of top end faces 311 are flush in the z direction; and/or the plurality of bottom end faces 312 are flush in the z direction.

In other words, according to at least one implementation of the present application, the semiconductor device comprises the word line structure, the back gate structure and the semiconductor pillars arranged in an array, wherein the back gate structure comprises the bottom end face close to the bottom end of the semiconductor pillar and the top end face close to the top end of the semiconductor pillar. In an example, the top end faces of the plurality of back gate structures are flush relative to the same reference plane in the z direction. In an example, the bottom end faces of the plurality of back gate structures are flush relative to the same reference plane in the z direction. In an example, the top end faces of the plurality of back gate structures are flush relative to the same reference plane in the z direction, and the bottom end faces of the plurality of back gate structures are flush relative to the same reference plane in the z direction. It is to be noted that, due to the limitation of the process, the error range relative to the same reference plane described above may be between −10% to 10%.

At least one of the top end faces and the bottom end faces of the different back gate structures is flush relative to the reference plane in the z direction, which improves the consistency of the back gate structures and can enhance the connection stability of the back gate structures with a reference voltage output end.

It may be understood that, the back gate conductive layer of the back gate structure may comprise a bottom end face and a top end face that are opposite in the z direction. The bottom end faces of the plurality of back gate structures being flush relative to the same reference plane in the z direction may be understood as the bottom end faces of the back gate conductive layers of the different back gate structures being flush relative to the same reference plane in the z direction. The top end faces of the plurality of back gate structures being flush relative to the same reference plane in the z direction may be understood as the top end faces of the back gate conductive layers of the different back gate structures being flush relative to the same reference plane in the z direction.

Furthermore, as shown in FIGS. 1 and 2, in order to enhance the gate control capability of the word line structure (which may be understood as the gate structure) and improve the switching speed of the word line structure, in an example, the lower end face 212 of the first word line structure 201 and the lower end face 212 of the second word line structure 202 are lower than the bottom end face 312 of the back gate structure 300 in the z direction. In an example, the upper end face 211 of the first word line structure 201 and the upper end face 211 of the second word line structure 202 are higher than the top end face 311 of the back gate structure 300 in the z direction. In an example, the lower end face 212 of the first word line structure 201 and the lower end face 212 of the second word line structure 202 are lower than the bottom end face 312 of the back gate structure 300 in the z direction, and the upper end face 211 of the first word line structure 201 and the upper end face 211 of the second word line structure 202 are higher than the top end face 311 of the back gate structure 300 in the z direction.

It may be understood that, the lower end face 212 of the first word line structure 201 and the lower end face 212 of the second word line structure 202 being lower than the bottom end face 312 of the back gate structure 300 in the z direction may be understood as the lower end faces of the word line conductor layers of the plurality of first word line structures 201 and the lower end faces of the word line conductor layers of the plurality of second word line structures 202 being lower than the bottom end face of the back gate conductive layer of the back gate structure 300 in the z direction; and the upper end faces 211 of the first word line structures 201 and the upper end faces 211 of the second word line structures 202 being higher than the top end face 311 of the back gate structure 300 in the z direction may be understood as the upper end faces of the word line conductor layers of the plurality of first word line structures 201 and the upper end faces of the word line conductor layers of the plurality of second word line structures 202 being higher than the top end face of the back gate conductive layer of the back gate structure 300 in the z direction.

Furthermore, as shown in FIG. 1, the semiconductor device 1000 further comprises a covering dielectric layer 600 that is at least located between the adjacent semiconductor pillars 100. In an example, the covering dielectric layer 600 may comprise any suitable dielectric material, for example, an oxide. In an example, the covering dielectric layer 600 may comprise at least one of silicon oxide, silicon nitride, silicon oxynitride or high-k dielectric. For example, the covering dielectric layer 600 may comprise silicon oxide.

Furthermore, as an alternative, as described below in detail in conjunction with the drawings, a plurality of portions of the covering dielectric layer 600 located in different positions in the semiconductor device 1000 may be formed in different fabrication operations of the semiconductor device respectively, and since the same material is used for fabrication, the plurality of portions described above have no obvious boundary therebetween.

As such, according to the semiconductor device provided by at least one implementation of the present application, the semiconductor device may comprise the word line structure and a plurality of semiconductor pillars arranged in an array, wherein the plurality of semiconductor pillars are arranged in rows to form rows of semiconductor pillars, the word line structure is disposed between the adjacent rows of semiconductor pillars and comprises the first word line structure and the second word line structure spaced apart from each other, and the adjacent rows of semiconductor pillars are connected with one of the first word line structure and the second word line structure respectively. Since sub-word line structures (which may be understood as the first word line structure and the second word line structure) connecting the adjacent rows of semiconductor pillars are spaced from each other, occurrences of short circuit between the sub-word line structures may be reduced, and the electrical performance of the semiconductor device can be improved.

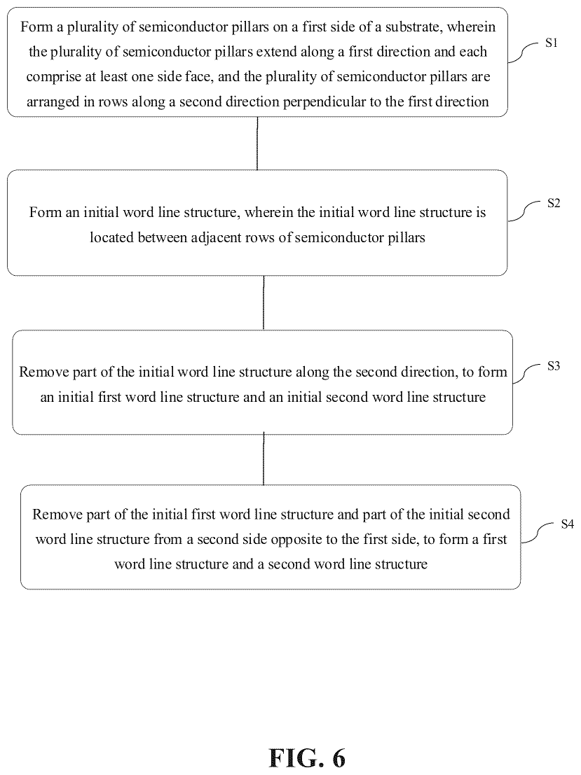

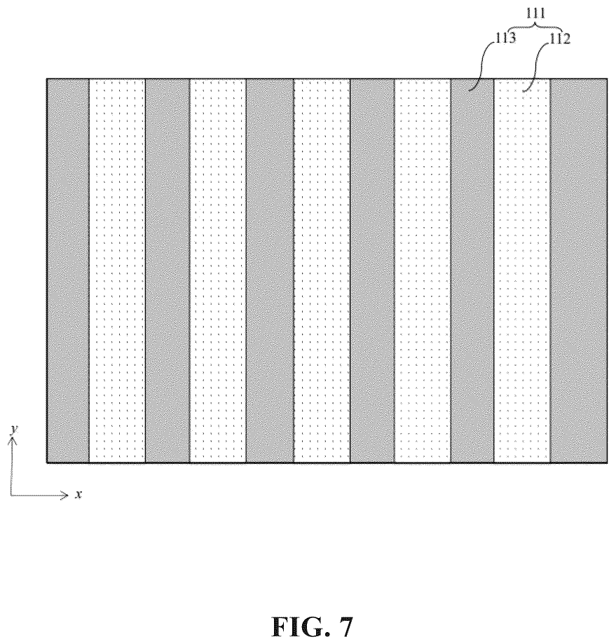

Some implementations of the present application provide a manufacturing method of a semiconductor device. FIG. 6 is a flow diagram of a method 2000 of fabricating a semiconductor device according to example implementations of the present application. FIGS. 7-39 are respectively process diagrams of the fabrication method 2000 of the semiconductor device according to one implementation of the present application.

As shown in FIG. 6, the present application provides a fabrication method 2000 of a semiconductor device, comprising:
S1, forming a plurality of semiconductor pillars on a first side of a substrate, wherein the plurality of semiconductor pillars extend along a first direction and each comprise at least one side face, and the plurality of semiconductor pillars are arranged in rows along a second direction perpendicular to the first direction;
S2, forming an initial word line structure, wherein the initial word line structure is located between adjacent rows of semiconductor pillars;
S3, removing part of the initial word line structure along the second direction, to form an initial first word line structure and an initial second word line structure; and
S4, removing part of the initial first word line structure and part of the initial second word line structure from a second side opposite to the first side, to form a first word line structure and a second word line structure.

Particular processes of various operations of the above-mentioned fabrication method 2000 in Example 1 will be illustrated in detail in conjunction with FIGS. 6 to 33.

### Example 1

### Operation S1

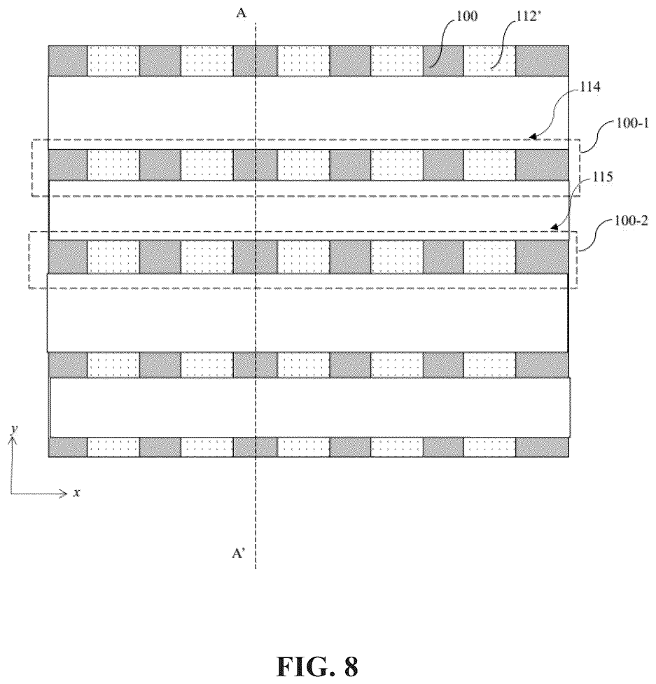

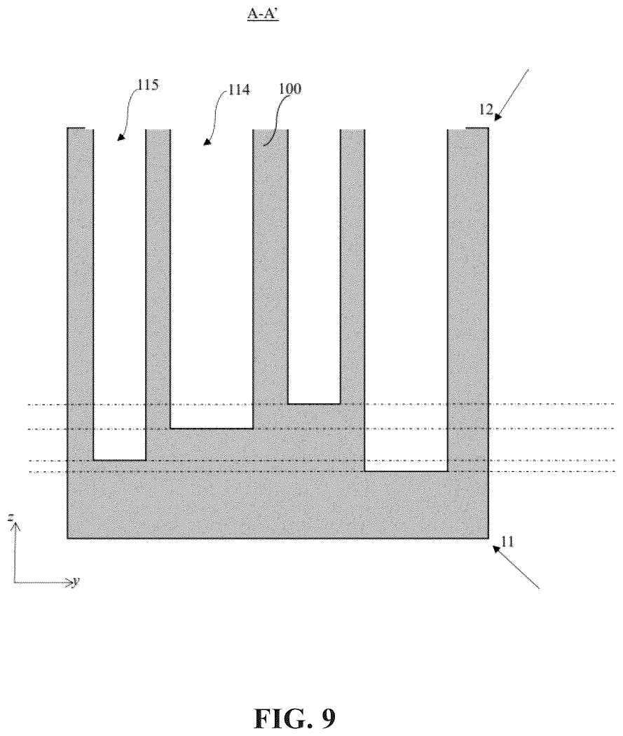

FIG. 7 is a top view of forming a base structure 111 of the fabrication method according to one implementation of the present application. FIG. 8 is a top view of a structure formed after forming a first trench 114 and a second trench 115 of the fabrication method according to one implementation of the present application. FIG. 9 is a cross-sectional view of an intermediate structure shown in FIG. 8 taken along a line A-A′.

As shown in FIGS. 6 to 9, operation S1, forming the plurality of semiconductor pillars on the first side of the substrate, wherein the plurality of semiconductor pillars extend along the first direction and each comprise at least one side face, and the plurality of semiconductor pillars are arranged in rows along the second direction perpendicular to the first direction, may, for example, comprise: forming a base structure 111, wherein the base structure 111 comprises semiconductor layers 113 and separation layers 112 distributed alternately in an x direction, wherein the x direction, y direction and z direction intersect each other; and forming first trenches 104 and second trenches 105 extending in the base structure 101 along the z direction from a first side 12 respectively, wherein the plurality of first trenches 104 and the plurality of second trenches 105 are distributed alternately in the y direction to divide the semiconductor layers 113 into the plurality of semiconductor pillars 100.

In an example, in one implementation of the present application, a material of fabricating the substrate (not shown) may be selected from any suitable semiconductor materials, which, for example, may include monocrystalline silicon (Si), monocrystalline germanium (Ge), silicon germanium (GeSi), silicon carbide (SiC), silicon on insulator (SOI), germanium on insulator (GOI), or III-V compounds, such as gallium arsenide, etc. As an alternative, monocrystalline silicon may be selected for the substrate.

In one implementation of the present application, the substrate may be, for example, a composite substrate for supporting a device structure thereon. A plurality of layers fabricated from different materials may be sequentially disposed through a thin film deposition process such as chemical vapor deposition (CVD), physical vapor deposition (PVD), atomic layer deposition (ALD) or any combination thereof, to form the substrate.

In one implementation of the present application, the substrate may comprise a substrate sacrificial layer. In an example, the substrate sacrificial layer may comprise a single layer, multiple layers or a suitable composite layer. For example, the substrate sacrificial layer may comprise one or more of any of a silicon oxide layer, a silicon nitride layer and a silicon oxynitride layer. As an alternative, the substrate sacrificial layer may be a high dielectric constant dielectric layer. As another alternative, the substrate sacrificial layer may comprise a dielectric layer, a sacrificial layer and a dielectric layer disposed sequentially, wherein the dielectric layer may be a silicon nitride layer, and the sacrificial layer may be a silicon oxide layer. As yet another alternative, the substrate sacrificial layer may comprise one or more of any of a dielectric material, a semiconductor material and a conductive material. For example, the sacrificial layer may comprise monocrystalline silicon or polysilicon. In an example, in one implementation of the present application, an example material of forming the sacrificial layer may comprise polysilicon.

Furthermore, part of a region of the substrate may also form a well region formed by doping an N-type or P-type dopant via an ion implantation or diffusion process. The dopant may comprise any one or a combination of phosphorus (P), arsenic (As) and antimony (Sb); or any one or a combination of boron (B), gallium (Ga) or indium (In). In some implementations of the present application, the well region may be fabricated by selecting the same dopant, or fabricated by selecting different dopants, and further, a doping concentration of the well region may be the same or may be different, which is not limited by the present application.

After the formation of the substrate, for example, a dry etching process or a combination of a dry etching process and a wet etching process may be used for formation. Furthermore, other manufacturing processes, for example, a patterning process including photolithography, cleaning and chemical mechanical polishing, etc., may be also performed to remove part of the substrate to form a plurality of openings (not shown) distributed as being spaced apart along the x direction, wherein the remaining of the substrate is also distributed as being spaced apart in the x direction to form the plurality of semiconductor layers 113. Thereafter, the plurality of openings may be filled through a thin film deposition process such as chemical vapor deposition (CVD), physical vapor deposition (PVD), atomic layer deposition (ALD) or any combination thereof to form the separation layer 112. The separation layer 112 may be formed using any suitable dielectric materials. In an example, the separation layer 112 may comprise at least one of silicon oxide, silicon nitride, silicon oxynitride or high-k dielectric.

As shown in FIGS. 8 and 9, after the formation of the base structure 111, a dry etching process or a combination of a dry etching process and a wet etching process may be used for formation. Furthermore, other manufacturing processes, for example, a patterning process including photolithography, cleaning and chemical mechanical polishing, etc., may be also performed to respectively form the first trenches 114 and the second trenches 115 extending in the base structure 111 along the z direction from the first side 12, wherein the plurality of first trenches 114 and the plurality of second trenches 115 are distributed alternately in the y direction to divide the semiconductor layer 113 into the plurality of semiconductor pillars 100. Furthermore, in the above-mentioned operation, a first separation layer 112′ is formed after part of the separation layer 112 is removed.

The plurality of semiconductor pillars 100 are arranged in an array in an x-y plane, wherein the plurality of semiconductor pillars 100 are arranged in rows in the x direction, for example, a first row of semiconductor pillars 100-1 and a second row of semiconductor pillars 100-2. Furthermore, the plurality of rows of semiconductor pillars are arranged as being spaced apart in the y direction.

In an example, extending lengths of the plurality of first trenches 114 in the z direction may be different. Likewise, extending lengths of the plurality of second trenches 115 in the z direction may be different. As described above, initial word line structures and initial back gate structures will be subsequently formed in the first trenches and the second trenches, such that extend lengths of the plurality of initial word line structures in the z direction may be also different, and extending lengths of the plurality of initial back gate structures in the z direction may be also different. By removing part of the initial word line structures and part of the initial back gate structures from a backside opposite to the first side, word line structures having flush surfaces in the z direction on the backside and back gate structures having flush surfaces in the z direction on the backside may be formed, thereby improving the structural consistency of memory cells in the semiconductor device and the impact of a structure difference on the performance of the semiconductor device. As described above, the extending lengths of the plurality of initial word line structures in the z direction and the extending lengths of the plurality of initial back gate structures in the z direction are allowed to be different, which can reduce the difficulty of the etching process and increase the process window of fabricating the semiconductor device.

### Operation S2

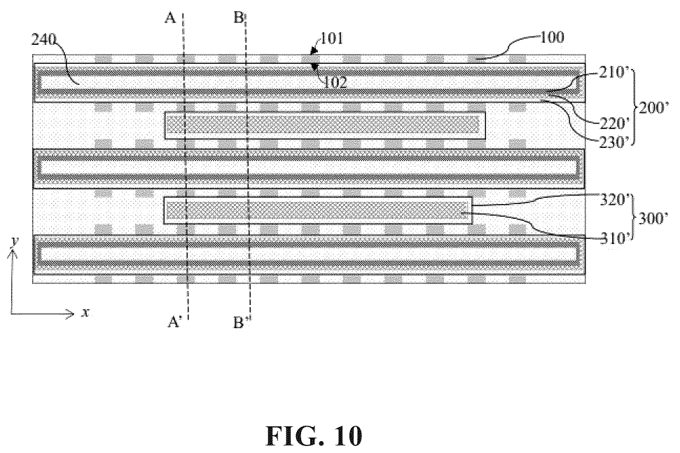

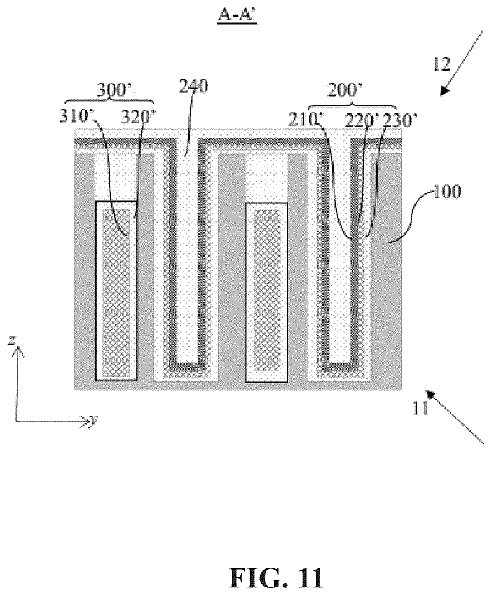

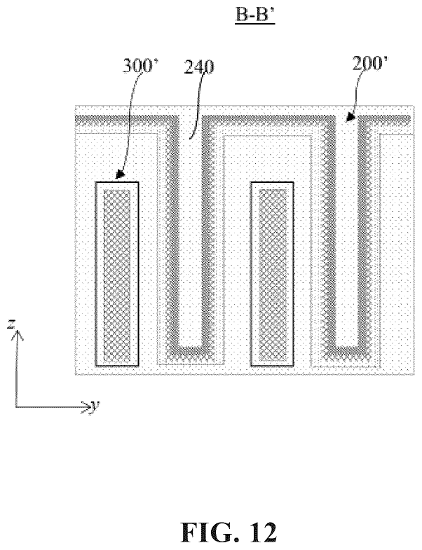

FIG. 10 is a top view of forming an initial word line structure 200′ of the fabrication method according to one implementation of the present application. FIG. 11 is a cross-sectional view of an intermediate structure shown in FIG. 10 taken along a line A-A′. FIG. 12 is a cross-sectional view of an intermediate structure shown in FIG. 10 taken along a line B-B′.

As shown in FIGS. 8-12, operation S2, forming the initial word line structure, wherein the initial word line structure is located between the adjacent rows of semiconductor pillars, may, for example, comprise: forming the initial word line structure 200′ within the first trench 114, wherein the initial word line structure 200′ may comprise a first conductive layer and a first isolation layer 230′ from inside to outside.

In an example, the fabrication method 2000 of the semiconductor device further comprises forming an initial back gate structure 300′ extending along the x direction in a fabrication process of forming the initial word line structure 200′, wherein the initial word line structure 200′ and the initial back gate structure 300′ are disposed on two sides of a row of the semiconductor pillars along the y direction. It is to be noted that, the initial back gate structure may be also formed in a different fabrication process from the initial word line structure, which is not limited by the present application.

In one implementation of the present application, forming the initial word line structure 200′ comprises: forming the initial word line structure 200′ in the first trench 114 through one or more thin film deposition processes that may include, but are not limited to, chemical vapor deposition (CVD), physical vapor deposition (PVD), atomic layer deposition (ALD) or any combination thereof, wherein a first isolation layer 230′ is formed on a sidewall and a bottom of the first trench 104; and sequentially forming an initial gate adhesion layer 220′ and an initial gate metal layer 210′ on a surface of the first isolation layer 230′. The initial gate adhesion layer 220′ and the initial gate metal layer 210′ may be referred to as a first conductive layer.

In an example, the first isolation layer 230′ may comprise any suitable dielectric material, for example, silicon oxide, silicon nitride, silicon oxynitride or high-k dielectric. For example, the first isolation layer 230′ may comprise silicon oxide. Furthermore, the initial gate adhesion layer 220′ may include, but is not limited to, titanium, titanium nitride, tantalum, tantalum nitride, etc. In addition, the initial gate metal layer 210′ may comprise any suitable conductive material, for example, the gate metal layer 220 may include, but is not limited to, tungsten (W), cobalt (Co), copper (Cu), aluminum (Al), etc. The initial gate adhesion layer 220′ is used to block diffusion of metal materials in the initial gate metal layer 210′, and is further used to improve adhesion between the initial gate metal layer 210′ and the first isolation layer 230′.

In an example, a cross-sectional shape of the initial word line structure 200′ in the x-y plane may comprise at least one of a rectangular shape, a trapezoidal shape, a circular shape or an oval shape.

In an example, after the formation of the initial word line structure 200′, at least the remaining space of the first trench 114 may be also filled with a dielectric filling layer 240. The dielectric filling layer 240 may fill the remaining space of the first trench 114 and cover part of a surface of the formed initial word line structure 200′. The dielectric filling layer 240 may comprise any suitable dielectric material, for example, silicon oxide, silicon nitride, silicon oxynitride or high-k dielectric. In an example, the dielectric filling layer 240 and the first isolation layer 230′ may be fabricated from the same material.

In one implementation of the present application, forming the initial back gate structure 300′ comprises: forming the initial back gate structure 300′ in the second trench 115 through one or more thin film deposition process that may include, but are not limited to, chemical vapor deposition (CVD), physical vapor deposition (PVD), atomic layer deposition (ALD) or any combination thereof, wherein an initial back gate dielectric layer 320′ is formed on a sidewall and a bottom of the second trench 115; and the remaining space of the second trench 105 is filled with an initial back gate conductive layer 310′.

In an example, the initial back gate dielectric layer 320′ may comprise any suitable dielectric material, for example, silicon oxide, silicon nitride, silicon oxynitride or high-k dielectric. For example, the initial back gate dielectric layer 320′ may comprise silicon oxide. Furthermore, the initial back gate conductive layer 310′ may include, but is not limited to, titanium, titanium nitride, tantalum, tantalum nitride, etc.

As described above, in order to simplify the fabrication process and save the production cost, the initial back gate structure 300′ may be formed in a fabrication process of forming the initial word line structure 200′. In an example, the initial back gate dielectric layer 320′ may be formed in the fabrication process of forming the initial word line dielectric layer 230′, and the initial word line dielectric layer 230′ and the initial back gate dielectric layer 320′ are fabricated using the same material. In other words, the initial word line dielectric layer 230′ and the initial back gate dielectric layer 320′ may comprise insulation material layers fabricated from the same material. Likewise, in order to simplify the fabrication process and save the production cost, the initial back gate conductive layer 310′ and the initial gate adhesion layer 220′ may be fabricated using the same material. In other words, the initial gate adhesion layer 220′ and the initial back gate conductive layer 310′ may comprise conductive material layers of the same material.

### Operation S3

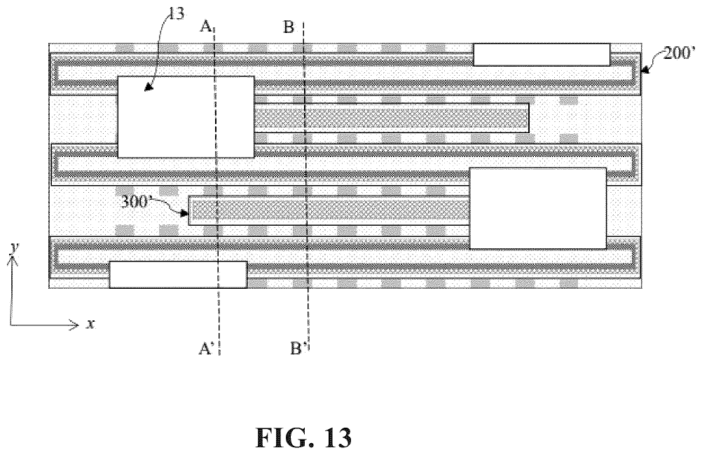

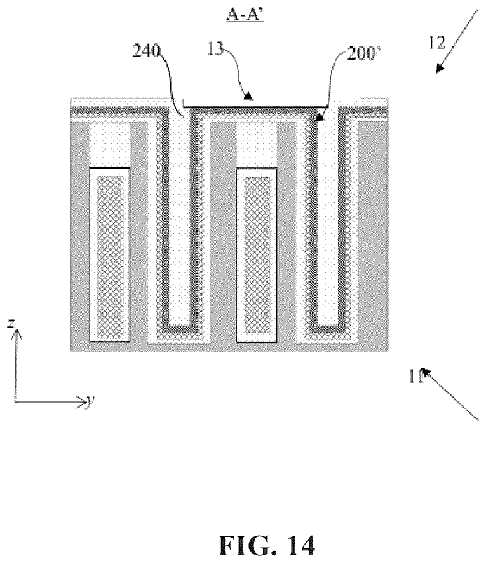

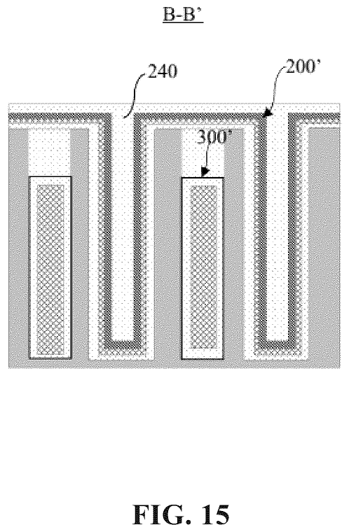

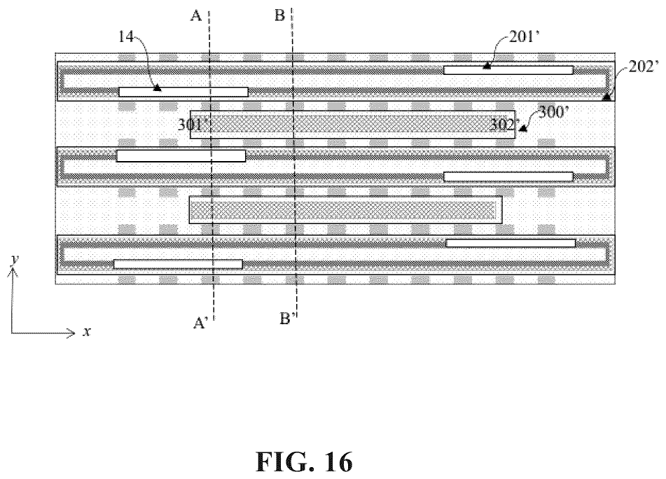

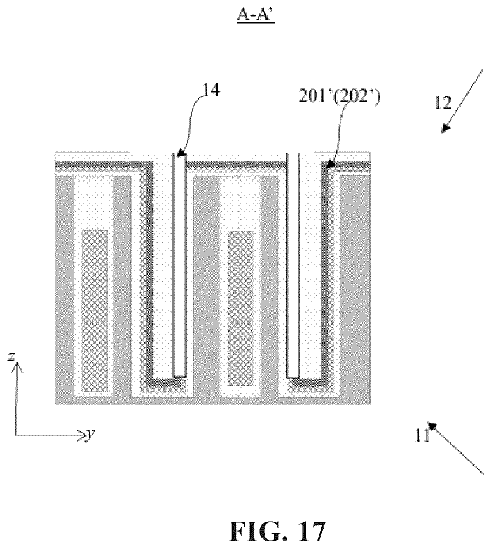

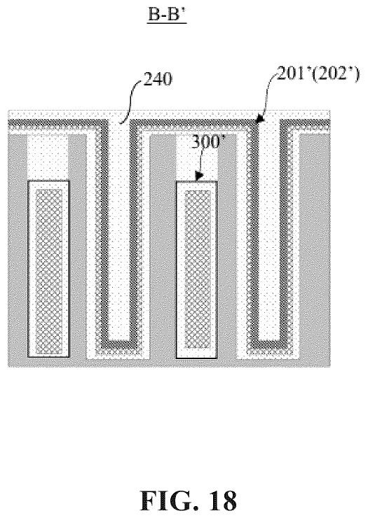

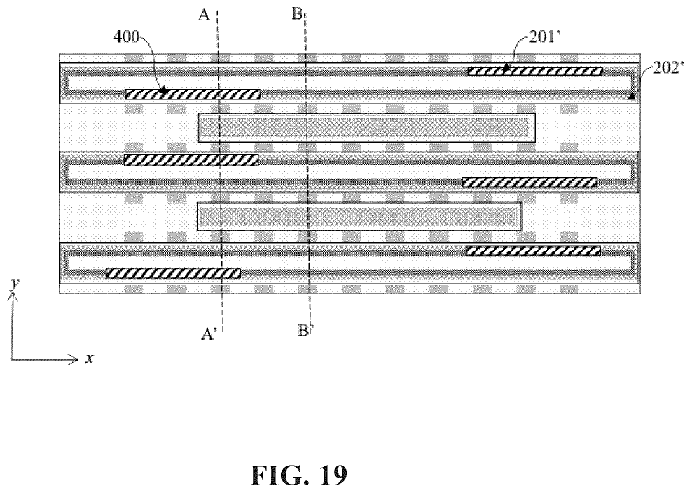

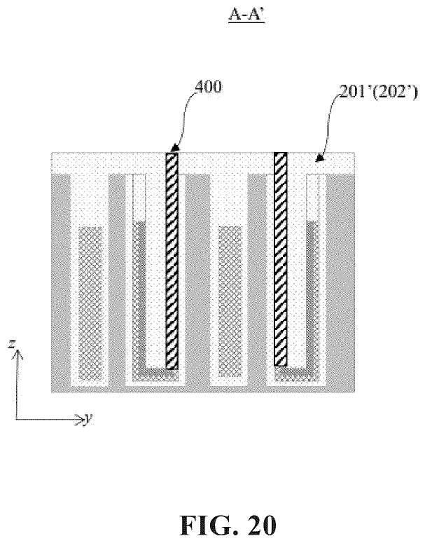

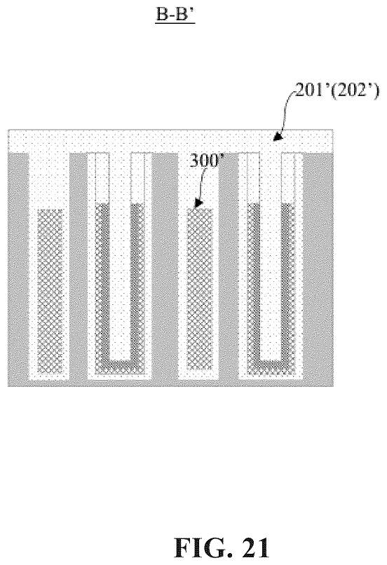

FIG. 13 is a top view after forming a first opening 13 of the fabrication method according to one implementation of the present application. FIG. 14 is a cross-sectional view of an intermediate structure shown in FIG. 13 taken along a line A-A′. FIG. 15 is a cross-sectional view of an intermediate structure shown in FIG. 13 taken along a line B-B′. FIG. 16 is a top view of forming a second opening 14 of the fabrication method according to one implementation of the present application. FIG. 17 is a cross-sectional view of an intermediate structure shown in FIG. 16 taken along a line A-A′. FIG. 18 is a cross-sectional view of an intermediate structure shown in FIG. 16 taken along a line B-B′. FIG. 19 is a top view after forming an isolation structure 400 of the fabrication method according to one implementation of the present application. FIG. 20 is a cross-sectional view of an intermediate structure shown in FIG. 19 taken along a line A-A′. FIG. 21 is a cross-sectional view of an intermediate structure shown in FIG. 19 taken along a line B-B′.

As shown in FIGS. 10-21, operation S3, removing part of the initial word line structure along the second direction to form the initial first word line structure and the initial second word line structure may, for example, comprise: removing part of the dielectric filling layer 240 from the first side 12 to form a first opening 13, and exposing the initial word line structure 200′ via the first opening 13; subsequently expand the first opening 13 along the z direction to form a second opening 14 splitting the initial word line structure 200′ into two portions; and filling the second opening 14 to form an isolation structure 400, the initial first word line structure 201′ and the initial second word line structure 202′.

In an example, as shown in FIGS. 10-15, for example, a dry etching process or a combination of a dry etching process and a wet etching process may be used for formation. Furthermore, other manufacturing processes, e.g., a patterning process including photolithography, cleaning and chemical mechanical polishing, etc., may be also performed to remove part of the dielectric filling layer 240 from the first side 12 to form the first opening 13. As shown in FIGS. 13 and 14, the first opening 13 exposes the initial word line structure 200′.

As shown in FIGS. 13-18, after exposing the initial word line structure 200′, a dry etching process or a combination of a dry etching process and a wet etching process may be continued to be used for formation. Furthermore, other manufacturing processes, e.g., a patterning process including photolithography, cleaning and chemical mechanical polishing, etc., may be also performed to continue to expand the first opening 13 along the z direction to form the second opening 14. The second opening 14 splits the initial word line structure 200′ into two portions, i.e., the initial first word line structure 201′ and the initial second word line structure 202′.

In an example, as shown in FIG. 17, the second opening 14 may extend to a bottom of the intermediate structure along the z direction. In other words, part of the initial word line structure 200′ extending along the z direction is removed via the first opening 13 to form the second opening 14. In an example, the process of forming the second opening 14 through an etching process may be completed by controlling the etching time and etching rate.

Furthermore, as shown in FIGS. 13, 16 and 17, the second opening 14 extends not only along the z direction, but also along the x direction. In an example, the initial back gate structure 300′ comprises two ends that are opposite in the x direction, for example, a first end 301′ and a second end 302′. During a process of forming the second opening 14, part of the initial word line structure 200′ removed along the x direction is opposite to at least one of the first end 301′ and the second end 302′ of the initial back gate structure 300′ in the y direction.

As shown in FIGS. 16-21, after the formation of the second opening 14, the second opening 14 is filled through one or more thin film deposition processes to form the isolation structure 400. The thin film deposition process may include, but is not limited to, chemical vapor deposition (CVD), physical vapor deposition (PVD), atomic layer deposition (ALD) or any combination thereof.

In an example, the isolation structure 400 may comprise any suitable dielectric material, for example, silicon oxide, silicon nitride, silicon oxynitride or high-k dielectric.

Furthermore, in one implementation of the present application, the isolation structure 400 has a higher etching selectivity ratio than the first isolation layer 230′ (as shown in FIG. 11) of the initial word line structure 200′. In other words, process parameters may be adjusted, such that an etching selectivity ratio between the isolation structure 400 and the first isolation layer 230′ is high enough. For example, the material and formation method of the isolation structure 400 are adjusted, or modification treatment is performed on the isolation structure 400, or a suitable etching reagent or an etching method is selected, such that in a process of removing the first isolation layer 230′ by an etching method in subsequent operation S4, part of the first isolation layer 230′ can be etched sufficiently without occurring under-etching, and it can be ensured that the etching process can accurately stop at the surface of the isolation structure 400, so as to avoid over-etching.

### Operation S4

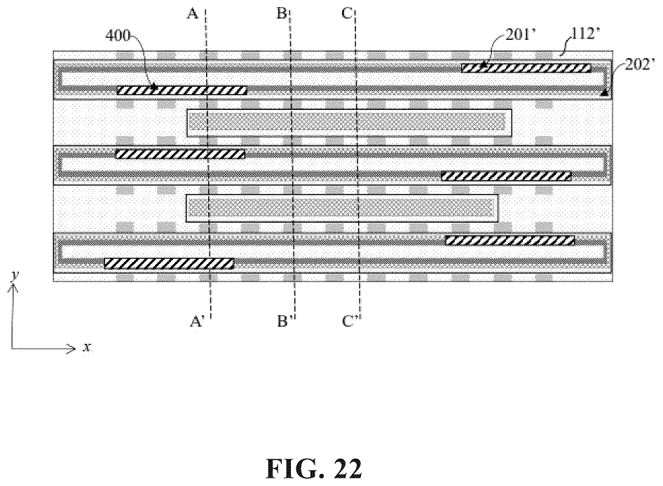

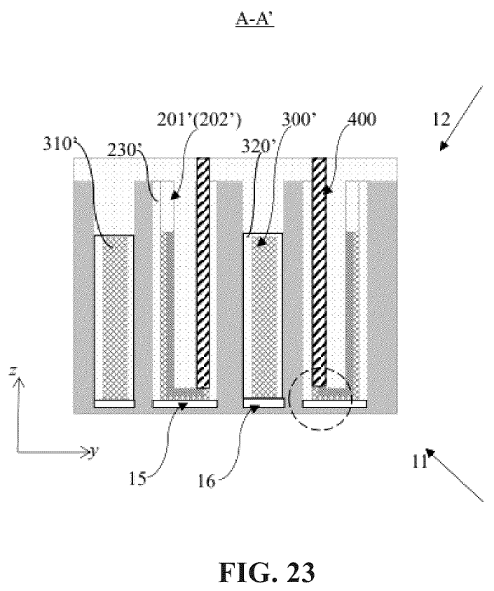

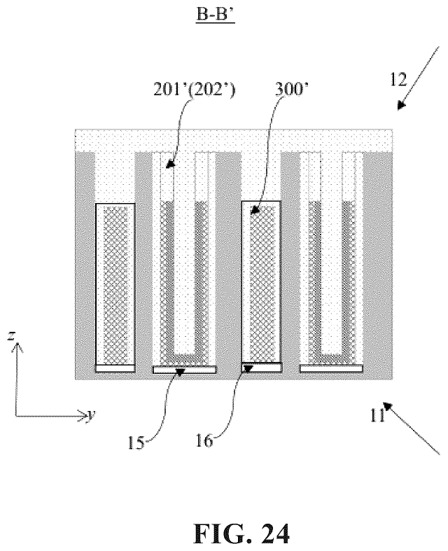

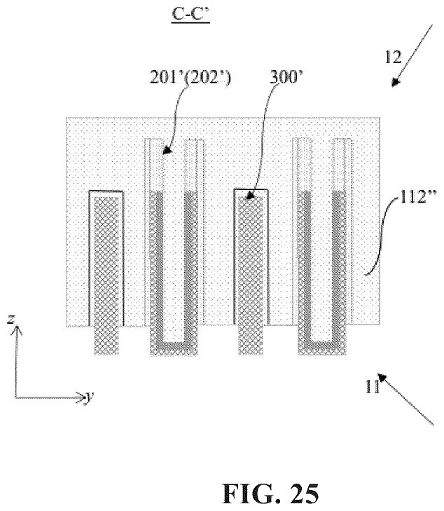

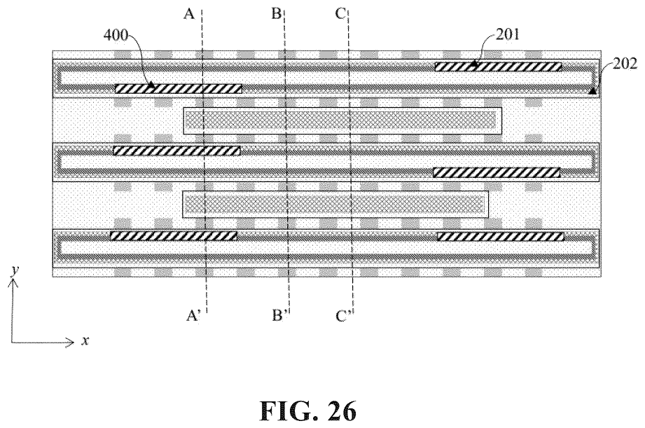

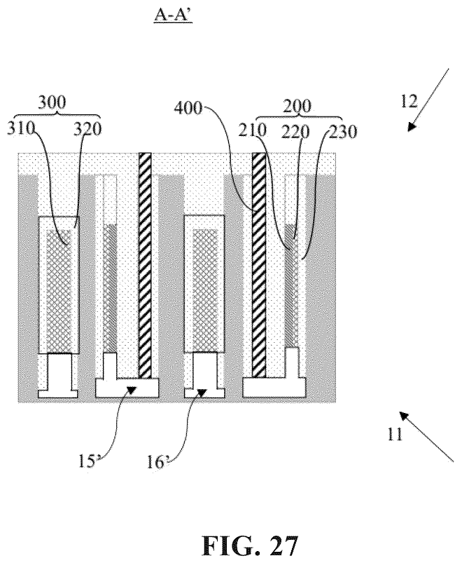

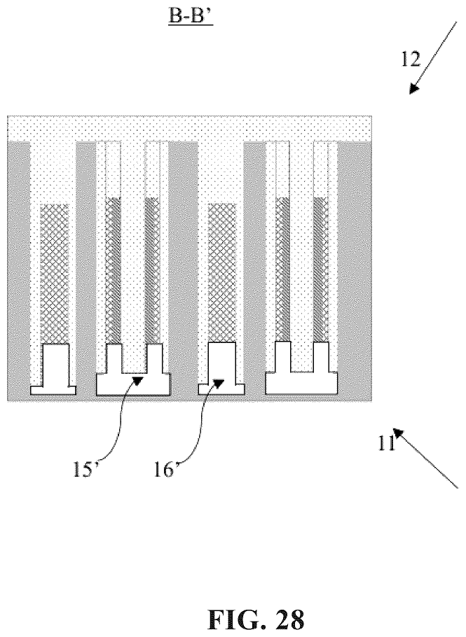

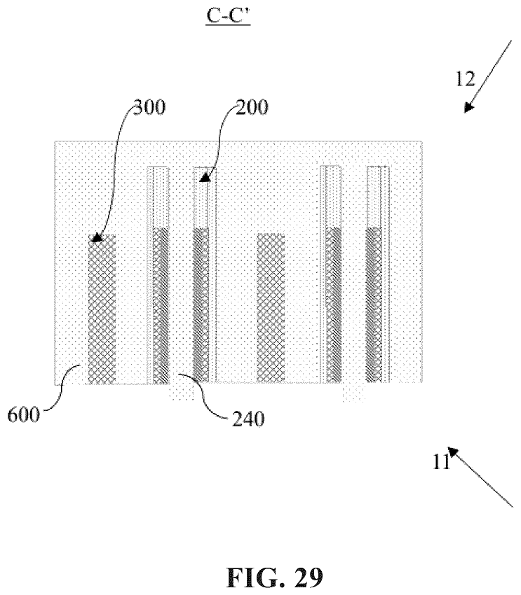

FIG. 22 is a top view after forming a second separation layer 112″ of the fabrication method according to one implementation of the present application. FIG. 23 is a cross-sectional view of an intermediate structure shown in FIG. 22 taken along a line A-A′. FIG. 24 is a cross-sectional view of an intermediate structure shown in FIG. 22 taken along a line B-B′. FIG. 25 is a cross-sectional view of an intermediate structure shown in FIG. 22 taken along a line C-C′. FIG. 26 is a top view after forming a first word line structure 201 and a second word line structure 202 of the fabrication method according to one implementation of the present application. FIG. 27 is a cross-sectional view of an intermediate structure shown in FIG. 26 taken along a line A-A′. FIG. 28 is a cross-sectional view of an intermediate structure shown in FIG. 26 taken along a line B-B′. FIG. 29 is a cross-sectional view of an intermediate structure shown in FIG. 26 taken along a line C-C′.

As shown in FIGS. 19-29, operation S4, removing part of the initial first word line structure and part of the initial second word line structure from the second side opposite to the first side to form the first word line structure and the second word line structure, may, for example, comprise: removing a part of the substrate, a part of the first isolation layer 230′ (as shown in FIG. 11) of the initial first word line structure 201′ and a part of the first isolation layer 230′ of the initial second word line structure 202′ from the second side 11 to expose a first conductive layer of the initial first word line structure 201′ and a first conductive layer of the initial second word line structure 202′; and removing a part of the first conductive layer of the initial first word line structure 201′ and a part of the first conductive layer of the initial second word line structure 202′ along the z direction to form the first word line structure 201 and the second word line structure 202.

Through the above operations, the remaining first isolation layer 230′ of the initial first word line structure 201′ forms a word line dielectric layer 230 of the first word line structure 201; and the remaining first isolation layer 230′ of the initial second word line structure 202′ forms a word line dielectric layer 230 of the second word line structure 202. The remaining first conductive layer of the initial first word line structure 201′ forms a word line conductor layer of the first word line structure 201, and the remaining first conductive layer of the initial second word line structure 202′ forms a word line conductor layer of the second word line structure 202. A lower end face of the word line conductor layer of the first word line structure 201 is higher than a lower end face of the word line dielectric layer 230 of the first word line structure 201 in the z direction; and a lower end face of the word line conductor layer of the second word line structure 202 is higher than a lower end face of the word line dielectric layer 230 of the second word line structure.

In an example, as shown in FIGS. 8 and 19-25, for example, a dry etching process or a combination of a dry etching process and a wet etching process is used for formation. Furthermore, other manufacturing processes, e.g., a patterning process including photolithography, cleaning and chemical mechanical polishing, etc., may be also performed to remove a part of the substrate, for example, a part of the first separation layer 112′, from the second side 11 to form a second separation layer 112″. In this operation, a part of the first isolation layer 230′ (as shown in FIG. 11) of the initial first word line structure 201′ and a part of the first isolation layer 230′ of the initial second word line structure 202′ may be also removed to form a first gap 15, to expose the first conductive layer of the initial first word line structure 201′ or the first conductive layer of the initial second word line structure 202′.

As shown in FIGS. 22-29, after the formation of the first gap 15, for example, a dry etching process or a combination of a dry etching process and a wet etching process may be used for formation. Furthermore, other manufacturing processes, e.g., a patterning process including photolithography, cleaning and chemical mechanical polishing, etc., may be also performed to subsequently remove a part of the first isolation layer 230′ of the initial first word line structure 201′ and a part of the first isolation layer 230′ of the initial second word line structure 202′, and remove a part of the first conductive layer of the initial first word line structure 201′ and a part of the first conductive layer of the initial second word line structure 202′ via the first gap 15 from the second side 11 to the first side 12 along the z direction to form the first word line structure 201 and the second word line structure 202, thereby forming a third gap 15′.

Through the above operations, the remaining first isolation layer 230′ of the initial first word line structure 201′ forms a word line dielectric layer 230 of the first word line structure 201; and the remaining first isolation layer 230′ of the initial second word line structure 202′ forms a word line dielectric layer 230 of the second word line structure 202. The remaining first conductive layer of the initial first word line structure 201′ forms a word line conductor layer of the first word line structure 201, and the remaining first conductive layer of the initial second word line structure 202′ forms a word line conductor layer of the second word line structure 202. The word line conductor layer of the first word line structure 201 and the word line conductor layer of the second word line structure 202 may each comprise a word line adhesion layer 220 and a word line metal layer 210.

Furthermore, with reference to FIGS. 19-29 again, in one implementation of the present application, in a fabrication process of removing part of the initial first word line structure 201′ and part of the initial second word line structure 202′ to form the first word line structure 201 and the second word line structure 202, part of the initial back gate structure 300′ is removed from the second side 11 to form a back gate structure 300.

In an example, as shown in FIGS. 8 and 19-25, for example, a dry etching process or a combination of a dry etching process and a wet etching process is used for formation. Furthermore, other manufacturing processes, e.g., a patterning process including photolithography, cleaning and chemical mechanical polishing, etc., may be also performed to remove a part of the substrate, for example, a part of the first separation layer 112′, from the second side 11 to form a second separation layer 112″. In this operation, part of the initial back gate dielectric layer 320′ is removed to form a second gap 16, to expose the initial back gate conductive layer 310′ of the initial back gate structure 300′.

As shown in FIGS. 22-29, after the formation of the first gap 15 and the second gap 16, for example, a dry etching process or a combination of a dry etching process and a wet etching process may be used for formation. Furthermore, other manufacturing processes, e.g., a patterning process including photolithography, cleaning and chemical mechanical polishing, etc., may be also performed to remove part of the initial back gate conductive layer 310′ via the second gap 16 from the second side 11 to the first side 12 along the z direction to form a fourth gap 16′ and a back gate conductive layer 310, in the process of continuing to remove a part of the first isolation layer 230′ of the initial first word line structure 201′ and a part of the first isolation layer 230′ of the initial second word line structure 202′ and removing a part of the first conductive layer of the initial first word line structure 201′ and a part of the first conductive layer of the initial second word line structure 202′ via the first gap 15 from the second side 11 to the first side 12 along the z direction to form the first word line structure 201 and the second word line structure 202.

In an example, as shown in FIGS. 23 and 27, as described in operation S3, in this process, the continuing to remove a part of the first isolation layer 230′ of the initial first word line structure 201′ and a part of the first isolation layer 230′ of the initial second word line structure 202′ (as shown by a circular dashed box in FIG. 23) may stop at the isolation structure 400. By disposing an etching stop layer in a process of forming the word line dielectric layers of the first word line structure and the second word line structure, the etching processing may ensure a sufficient amount of etching, while reducing the occurrences of excessively deep etching, thereby reducing the possibility of degradation of electrical performance of the semiconductor device.

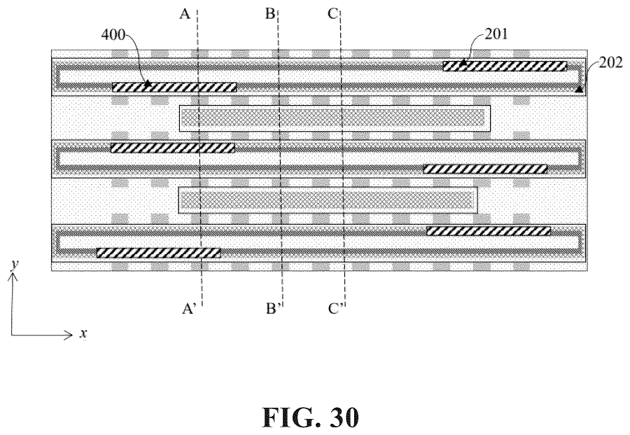

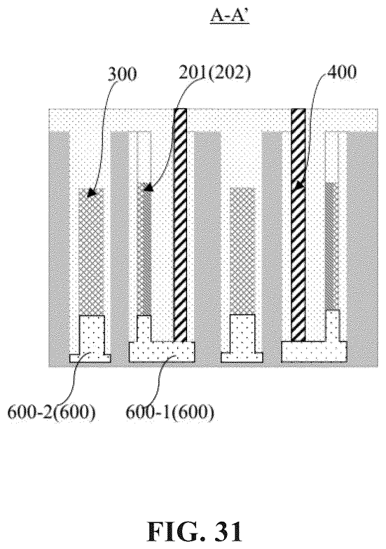

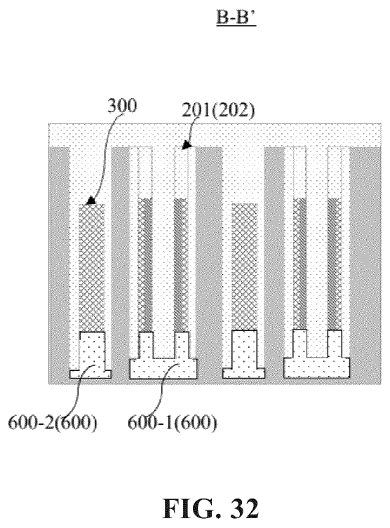

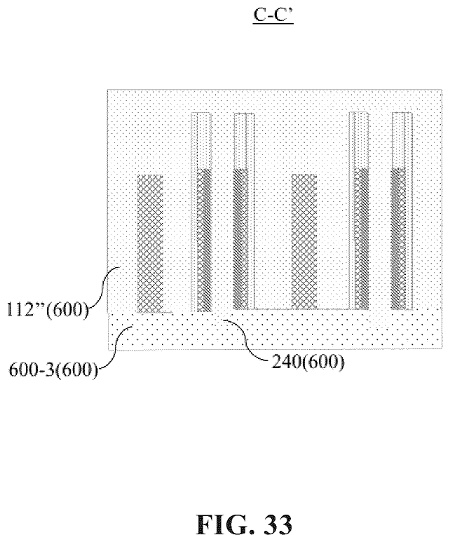

FIG. 30 is a top view after forming a first covering dielectric layer 600-1 and a second covering dielectric layer 600-2 of the fabrication method according to one implementation of the present application. FIG. 31 is a cross-sectional view of an intermediate structure shown in FIG. 30 taken along a line A-A′. FIG. 32 is a cross-sectional view of an intermediate structure shown in FIG. 30 taken along a line B-B′. FIG. 33 is a cross-sectional view of an intermediate structure shown in FIG. 30 taken along a line C-C′.

As shown in FIGS. 26-33, after forming the third gap 15′ and the fourth gap 16′, the first covering dielectric layer 600-1 and the second covering dielectric layer 600-2 may be formed through one or more thin film deposition processes that may include, but are not limited to, chemical vapor deposition (CVD), physical vapor deposition (PVD), atomic layer deposition (ALD) or any combination thereof.

In an example, both the first covering dielectric layer 600-1 and the second covering dielectric layer 600-2 may comprise any suitable dielectric material, for example, an oxide. In an example, both the first covering dielectric layer 600-1 and the second covering dielectric layer 600-2 may comprise at least one of silicon oxide, silicon nitride, silicon oxynitride or high-k dielectric. For example, both the first covering dielectric layer 600-1 and the second covering dielectric layer 600-2 may comprise silicon oxide.

Furthermore, as shown in FIGS. 25-33, after forming the third gap 15′ and the fourth gap 16′, a third covering dielectric layer 600-3 covering the second separation layer 112″ may be formed through one or more thin film deposition processes that may include, but are not limited to, chemical vapor deposition (CVD), physical vapor deposition (PVD), atomic layer deposition (ALD) or any combination thereof. In an example, the third covering dielectric layer 600-3 may comprise any suitable dielectric material, for example, an oxide. In an example, the third covering dielectric layer 600-3 may comprise at least one of silicon oxide, silicon nitride, silicon oxynitride or high-k dielectric. For example, the third covering dielectric layer 600-3 may comprise silicon oxide. The first covering dielectric layer 600-1, the second covering dielectric layer 600-2, the third covering dielectric layer 600-3 and the second separation layer 112″ may form the covering dielectric layer 600 as shown in FIG. 1.

Furthermore, when materials for fabricating the first covering dielectric layer 600-1, the second covering dielectric layer 600-2, the third covering dielectric layer 600-3 and the second separation layer 112″ are the same, the first covering dielectric layer 600-1, the second covering dielectric layer 600-2, the third covering dielectric layer 600-3 and the second separation layer 112″ have no obvious boundary therebetween.

Particular processes of various operations of the above-mentioned fabrication method 2000 in Example 2 will be illustrated in detail in conjunction with FIGS. 6 to 39.

### Example 2

Since the contents involved in the fabrication method 2000 of the semiconductor device as described in Example 1 above may be completely or partially applicable to the fabrication method of the semiconductor device described here (Example 2), the contents relevant or similar thereto are no longer repeated. However, those skilled in the art may understand that, the semiconductor device 1000 (as shown in FIGS. 1-5) may be formed according to the fabrication method 2000 of the semiconductor device as described in Example 1, and the semiconductor device 1000 may be also formed according to the fabrication method 2000 of the semiconductor device as described in Example 2. On this basis, both the fabrication methods 2000 of the semiconductor device as described in Examples 1 and 2 have the same advantageous effects as the semiconductor structure 1000, which is no longer repeated herein.

### Operation S3

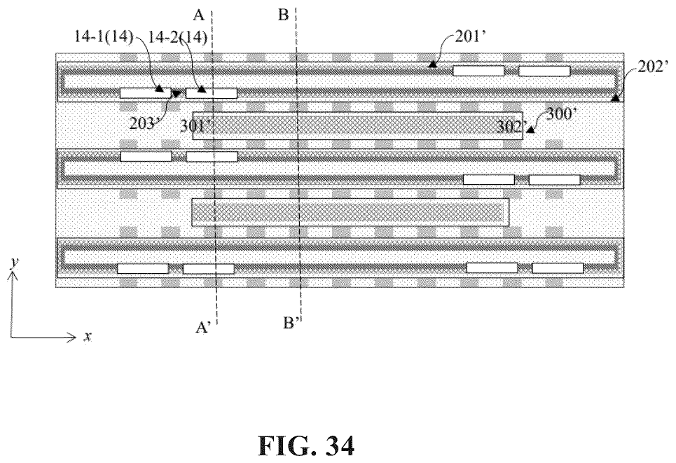

FIG. 34 is a top view after forming a second opening 14 of the fabrication method according to one implementation of the present application.

With reference to FIGS. 34, and 10-21, operation S3, removing part of the initial word line structure along the second direction to form the initial first word line structure and the initial second word line structure may, for example, comprise: sequentially removing a first portion (not shown) and a second portion (not shown) of the initial word line structure 200′ along the x direction, wherein part of the initial word line structure 200′ is spaced between the first portion and the second portion in the x direction.

In an example, after exposing the initial word line structure 200′, a dry etching process or a combination of a dry etching process and a wet etching process may be continued to be used for formation. Furthermore, other manufacturing processes, e.g., a patterning process including photolithography, cleaning and chemical mechanical polishing, etc., may be also performed to subsequently expand the first opening 13 along the z direction to form a second opening 14. The second opening 14 comprises a first second opening 14-1 and a second second opening 14-2, wherein part of the remained initial word line structure 200′ is spaced between the first second opening 14-1 and the second second opening 14-2 in the x direction. Part of the remained initial word line structure 200′ forms an initial third word line structure 203′ that may be used to form a third word line structure 203.

The second opening 14 comprising the first second opening 14-1 and the second second opening 14-2 splits the initial word line structure 200′ into two portions, i.e., the initial first word line structure 201′ and the initial second word line structure 202′.

In an example, as shown in FIG. 17, the second opening 14 may extend to a bottom of the intermediate structure along the z direction. In other words, part of the initial word line structure 200′ extending along the z direction is removed via the first opening 13 to form the second opening 14. In an example, the process of forming the second opening 14 through an etching process may be completed by controlling the etching time and etching rate.

### Operation S4

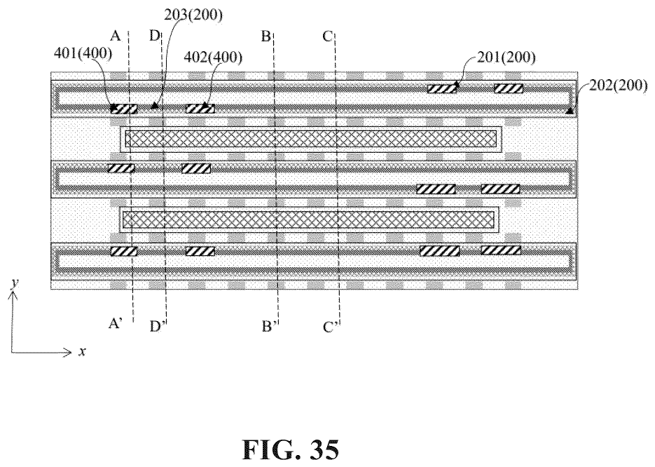

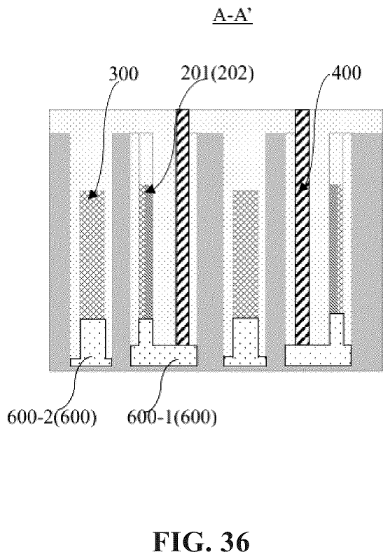

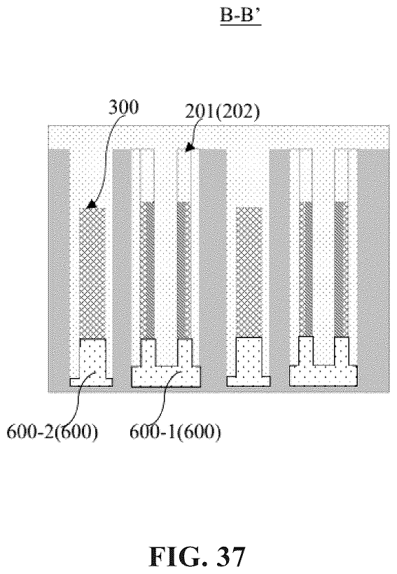

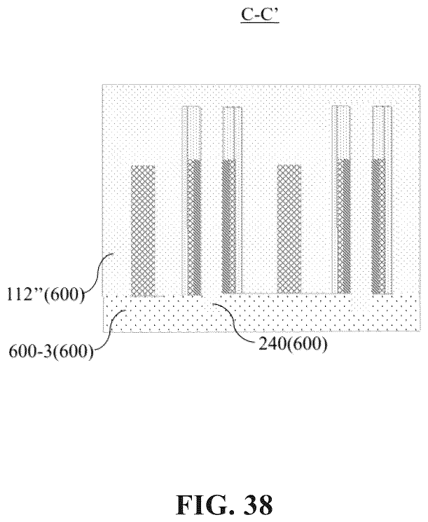

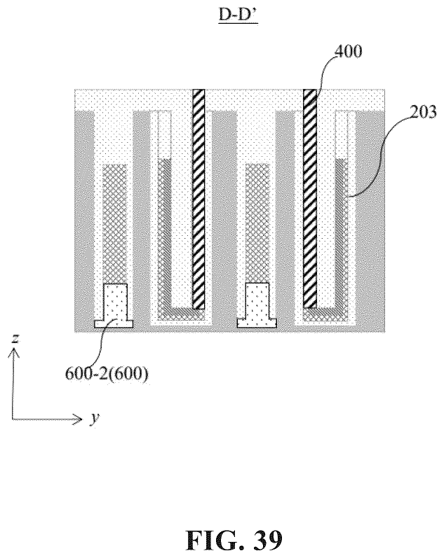

FIG. 35 is a top view after forming a first word line structure 201, a second word line structure 202 and a third word line structure 203 of the fabrication method according to one implementation of the present application. FIG. 36 is a cross-sectional view of an intermediate structure shown in FIG. 35 taken along a line A-A′. FIG. 37 is a cross-sectional view of an intermediate structure shown in FIG. 35 taken along a line B-B′. FIG. 38 is a cross-sectional view of an intermediate structure shown in FIG. 34 taken along a line C-C′. FIG. 39 is a cross-sectional view of an intermediate structure shown in FIG. 35 taken along a line D-D′.

As shown in FIGS. 34-39, in one implementation of the present application, in a fabrication process of removing part of the initial first word line structure 201′ and part of the initial second word line structure 202′ from the second side 11 to form the first word line structure 201 and the second word line structure 202, the initial third word line structure 203′ may be not removed. In other words, a cross-sectional shape of the third word line structure 203 in a plane (the y-z plane) perpendicular to the x direction comprises an L shape.

According to the fabrication method of the semiconductor device provided by at least one implementation of the present application, the semiconductor device may comprise the word line structure and the semiconductor pillars arranged in an array, wherein the plurality of semiconductor pillars are arranged in rows to form rows of semiconductor pillars, the word line structure is disposed between the adjacent rows of semiconductor pillars and comprises the first word line structure and the second word line structure spaced apart from each other, and the adjacent rows of semiconductor pillars are connected with one of the first word line structure and the second word line structure respectively. Since sub-word line structures (which may be understood as the first word line structure and the second word line structure) connecting the adjacent rows of semiconductor pillars are spaced from each other, occurrences of short circuit between the sub-word line structures may be reduced, and the electrical performance of the semiconductor device can be improved.

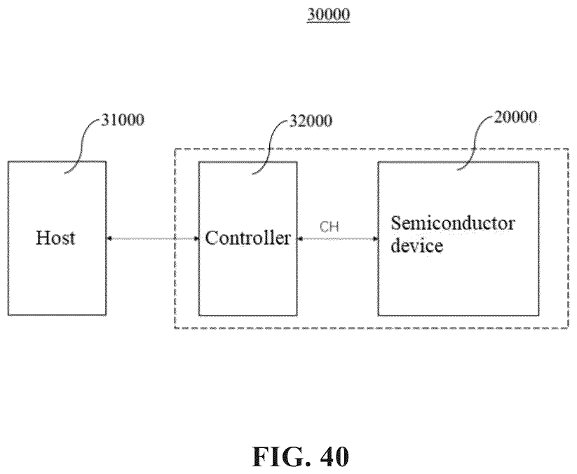

Additionally, FIG. 40 is a schematic structural diagram of a memory system 30000 according to one implementation of the present application.

As shown in FIG. 40, at least one implementation of yet another aspect of the present application further provides a memory system 30000. The memory system 30000 may comprise a semiconductor device 20000 and a controller 32000. The semiconductor device 20000 may be the same as the semiconductor device as described in any implementation above, which is no longer repeated in the present application. The semiconductor device 20000 may be a two-dimensional semiconductor device or a three-dimensional semiconductor device, or even a part of a two-dimensional semiconductor device or a part of a three-dimensional semiconductor device. An illustration will be made below by taking the three-dimensional semiconductor device as an example.

As an alternative, the three-dimensional semiconductor device may comprise at least one of a three-dimensional NAND memory and a three-dimensional NOR memory.

The memory system 30000 may comprise a semiconductor device 20000 and a controller 32000. The semiconductor device 20000 may be the same as the semiconductor device as described in any implementation above, which is no longer repeated in the present application. The controller 32000 may control the semiconductor device 20000 through a channel CH, and the semiconductor device 20000 may perform operations based on control of the controller 32000 in response to a request from a host 31000. The semiconductor device 20000 may receive a command CMD and an address ADDR from the controller 32000 through the channel CH, and access a region selected from a memory cell array in response to the address. In other words, the semiconductor device 20000 may perform an internal operation corresponding to the command on the region selected by the address.

In some implementations, the three-dimensional memory system may be implemented as, for example, a Universal Flash Storage (UFS) device, a solid-state drive (SSD), a multi-media card in the forms of MMC, eMMC, RS-MMC and micro-MMC, a secure digital card in the forms of SD, mini-SD and micro-SD, a memory device of a Personal Computer Memory Card International Association (PCMCIA) card type, a memory device of a Peripheral Component Interconnection (PCI) type, a memory device of a PCI-Express (PCI-E) type, a Compact Flash (CF) card, a smart media card, or a memory stick, etc. The memory system provided by the present application, as it is disposed with the semiconductor device provided by the present application, has the same advantageous effect as the semiconductor device, which is not repeated herein.

The present application provides a fabrication method of a semiconductor device, a semiconductor device and a memory system which can at least partially solve the above-mentioned problems existing in the related technologies or other problems in the field.

An aspect of the present application provides a semiconductor device which comprises a plurality of semiconductor pillars extending along a first direction and each comprising at least one side face, wherein the plurality of semiconductor pillars are arranged in rows along a second direction perpendicular to the first direction; and a word line structure located between a first row of semiconductor pillars and a second row of semiconductor pillars that are adjacent to each other, and comprising a first word line structure and a second word line structure spaced apart from the first word line structure, wherein the first word line structure is connected with a side face of the first row of semiconductor pillars; and the second word line structure is connected with a side face of the second row of semiconductor pillars.

In one implementation of the present application, the word line structure further comprises a third word line structure disposed between the first word line structure and the second word line structure in the second direction, wherein the third word line structure comprises a first sub-portion and a second sub-portion connected with each other; the first sub-portion extends on the side face of the semiconductor pillar along the first direction; and the second sub-portion extends along a third direction perpendicular to the first direction and the second direction.

In one implementation of the present application, a cross-sectional shape of the third word line structure in a plane perpendicular to the second direction comprises an L shape.

In one implementation of the present application, the semiconductor device further comprises an isolation structure.

The isolation structure is located between the first word line structure and the third word line structure in the second direction, and/or the isolation structure is located between the second word line structure and the third word line structure in the second direction.

In one implementation of the present application, the isolation structure extends along the first direction, and is connected with the second sub-portion in the second direction.

In one implementation of the present application, the semiconductor device further comprises a back gate structure extending along the second direction, wherein the word line structure and the back gate structure are distributed alternately in the third direction.

In one implementation of the present application, the back gate structure comprises two ends that are opposite in the second direction, wherein the ends and the isolation structure are oppositely disposed on two sides of the semiconductor pillars in the third direction; and the semiconductor device further comprises a ground structure connected with the ends.

In one implementation of the present application, the ends are disposed above the ground structure along the first direction.

In one implementation of the present application, the first word line structure and the second word line structure extend on the side face of the semiconductor pillar along the first direction respectively, and each comprises an upper end face and a lower end face that are opposite in the first direction, wherein a plurality of the upper end faces are flush in the first direction; and/or a plurality of the lower end faces are flush in the first direction.

In one implementation of the present application, the first word line structure and the second word line structure extend on the side face of the semiconductor pillar along the first direction respectively, and each comprises an upper end face and a lower end face that are opposite in the first direction; and the semiconductor device further comprises a back gate structure extending along the second direction, and the back gate structure comprises a top end face and a bottom end face that are opposite in the first direction, wherein in the first direction, the upper end face is higher than the top end face; and/or the lower end face is lower than the bottom end face.

Another aspect of the present application provides a method of fabricating a semiconductor device, comprising: forming a plurality of semiconductor pillars on a first side of a substrate, wherein the plurality of semiconductor pillars extend along a first direction and each comprise at least one side face, and the plurality of semiconductor pillars are arranged in rows along a second direction perpendicular to the first direction; forming an initial word line structure, wherein the initial word line structure is located between adjacent rows of the semiconductor pillars; removing part of the initial word line structure along the second direction to form an initial first word line structure and an initial second word line structure; and removing part of the initial first word line structure and part of the initial second word line structure from a second side opposite to the first side to form a first word line structure and a second word line structure.

In one implementation of the present application, the method further comprises: in a fabrication process of forming the initial word line structure, forming an initial back gate structure extending along the second direction, wherein the initial word line structure and the initial back gate structure are disposed on two sides of a row of the semiconductor pillars along a third direction, wherein the third direction is perpendicular to the first direction and the second direction.

In one implementation of the present application, the initial back gate structure comprises two ends that are opposite in the second direction; and the part of the initial word line structure removed along the second direction is opposite to the ends in the third direction.

In one implementation of the present application, the method further comprises: in a fabrication process of removing the part of the initial first word line structure and the part of the initial second word line structure to form the first word line structure and the second word line structure, removing part of the initial back gate structure from the second side to form a back gate structure.

In one implementation of the present application, removing the part of the initial word line structure along the second direction comprises: removing a first portion and a second portion of the initial word line structure sequentially along the second direction, wherein the part of the initial word line structure is spaced between the first portion and the second portion in the second direction.

In one implementation of the present application, the method further comprises: in a fabrication process of removing the part of the initial first word line structure and the part of the initial second word line structure to form the first word line structure and the second word line structure, retaining the part of the initial word line structure spaced therebetween, to form a third word line structure.

In one implementation of the present application, the initial word line structure comprises a first conductive layer and a first isolation layer from inside to outside, and removing the part of the initial first word line structure and the part of the initial second word line structure from the second side opposite to the first side to form the first word line structure and the second word line structure comprises: removing a part of the substrate, a part of the first isolation layer of the initial first word line structure and a part of the first isolation layer of the initial second word line structure from the second side, to expose the first conductive layer of the initial first word line structure and the first conductive layer of the initial second word line structure; continuing to remove a part of the first isolation layer of the initial first word line structure and a part of the first isolation layer of the initial second word line structure along the first direction, and removing a part of the first conductive layer of the initial first word line structure and a part of the first conductive layer of the initial second word line structure, to form the first word line structure and the second word line structure, wherein in the first direction, a lower end face of the remaining first conductive layer of the first word line structure is higher than a lower end face of the remaining first isolation layer of the first word line structure; and in the first direction, a lower end face of the remaining first conductive layer of the second word line structure is higher than a lower end face of the remaining first isolation layer of the second word line structure.

In one implementation of the present application, the method further comprises: after removing the part of the initial word line structure along the second direction, forming an isolation structure in a gap formed after removing the part of the initial word line structure; and in a fabrication process of continuing to remove a part of the first isolation layer of the initial first word line structure and a part of the first isolation layer of the initial second word line structure, the continuing to remove a part of the first isolation layer of the initial first word line structure and a part of the first isolation layer of the initial second word line structure stops at the isolation structure.

In one implementation of the present application, a cross-sectional shape of the initial word line structure in a plane perpendicular to the first direction comprises at least one of a rectangular shape, a trapezoidal shape, a circular shape or an oval shape.

Yet another aspect of the present application provides a memory system, comprising the semiconductor device provided by an aspect of the present application, and a controller coupled with the semiconductor device, wherein the controller is configured to store data to the semiconductor device.

According to the semiconductor device and the fabrication method, and the memory system provided by at least one implementation of the present application, the semiconductor device may comprise the word line structure and a plurality of semiconductor pillars arranged in an array, wherein the plurality of semiconductor pillars are arranged in rows to form rows of semiconductor pillars, the word line structure is disposed between the adjacent rows of semiconductor pillars and comprise the first word line structure and the second word line structure spaced apart from each other, and the adjacent rows of semiconductor pillars are connected with one of the first word line structure and the second word line structure respectively. Since sub-word line structures (which may be understood as the first word line structure and the second word line structure) connecting the adjacent rows of semiconductor pillars are spaced from each other, occurrences of short circuit between the sub-word line structures may be reduced, and the electrical performance of the semiconductor device can be improved.

Although an example fabrication method and an example structure of the semiconductor device have been described here, it may be understood that one or more features may be omitted, substituted or added from a structure of the semiconductor device. Furthermore, the listed materials of various layers are merely examples.

The above descriptions are merely descriptions of some implementations of the present application and applied technical principles. Those skilled in the art should understand that, the protection scope of the present application is not limited to the technical solutions formed by a selected combination of the above technical features, but should also encompass other technical solutions formed by any combination of the above technical features or equivalent features thereof without departing from the technical concept, for example, technical solutions formed by interchanging of the above features and the technical features with similar functions as disclosed (but not limited to those) in the present application.

The above descriptions are merely descriptions of implementations of the present application and applied technical principles. Those skilled in the art should understand that, the protection scope of the present application is not limited to the technical solutions formed by specific combinations of the above technical features, but should also encompass other technical solutions formed by any combination of the above technical features or equivalent features thereof, without departing from the technical concept, for example, technical solutions formed by interchanging the above features with the technical features with similar functions as disclosed (but not limited to those) in the present application.

What is claimed is:

1. A semiconductor device, comprising:
a plurality of semiconductor pillars extending along a first direction and each comprising at least one side face, wherein the plurality of semiconductor pillars are arranged in rows along a second direction perpendicular to the first direction; and
a word line structure located between a first row of semiconductor pillars and a second row of semiconductor pillars that are adjacent to each other, and comprising a first word line structure and a second word line structure spaced apart from the first word line structure,
wherein the first word line structure is connected with a side face of the first row of semiconductor pillars; and
the second word line structure is connected with a side face of the second row of semiconductor pillars.

2. The semiconductor device of claim 1, wherein
the word line structure further comprises a third word line structure disposed between the first word line structure and the second word line structure in the second direction,
wherein the third word line structure comprises a first sub-portion and a second sub-portion connected with each other;
the first sub-portion extends on the side face of the semiconductor pillar along the first direction; and
the second sub-portion extends along a third direction perpendicular to the first direction and the second direction.

3. The semiconductor device of claim 2, wherein
a cross-sectional shape of the third word line structure in a plane perpendicular to the second direction comprises an L shape.

4. The semiconductor device of claim 2, wherein
the semiconductor device further comprises an isolation structure,
wherein the isolation structure is located between the first word line structure and the third word line structure in the second direction; and/or
the isolation structure is located between the second word line structure and the third word line structure in the second direction.

5. The semiconductor device of claim 4, wherein
the isolation structure extends along the first direction, and is connected with the second sub-portion in the second direction.

6. The semiconductor device of claim 4, wherein
the semiconductor device further comprises a back gate structure extending along the second direction,
wherein the word line structure and the back gate structure are distributed alternately in the third direction.

7. The semiconductor device of claim 6, wherein
the back gate structure comprises two ends that are opposite in the second direction,
wherein the ends and the isolation structure are oppositely disposed on two sides of the semiconductor pillars in the third direction; and
the semiconductor device further comprises a ground structure connected with the ends.

8. The semiconductor device of claim 7, wherein
the ends are disposed above the ground structure along the first direction.

9. The semiconductor device of claim 1, wherein
the first word line structure and the second word line structure extend on the side face of the semiconductor pillar along the first direction respectively, and each comprises an upper end face and a lower end face that are opposite in the first direction,
wherein a plurality of the upper end faces are flush in the first direction; and/or
a plurality of the lower end faces are flush in the first direction.

10. The semiconductor device of claim 1, wherein
the first word line structure and the second word line structure extend on the side face of the semiconductor pillar along the first direction respectively, and each comprises an upper end face and a lower end face that are opposite in the first direction; and
the semiconductor device further comprises a back gate structure extending along the second direction, and the back gate structure comprises a top end face and a bottom end face that are opposite in the first direction,
wherein in the first direction, the upper end face is higher than the top end face; and/or
the lower end face is lower than the bottom end face.

11. A method of fabricating a semiconductor device, comprising:
forming a plurality of semiconductor pillars on a first side of a substrate, wherein the plurality of semiconductor pillars extend along a first direction and each comprise at least one side face, and the plurality of semiconductor pillars are arranged in rows along a second direction perpendicular to the first direction;
forming an initial word line structure, wherein the initial word line structure is located between adjacent rows of the semiconductor pillars;
removing part of the initial word line structure along the second direction to form an initial first word line structure and an initial second word line structure; and
removing part of the initial first word line structure and part of the initial second word line structure from a second side opposite to the first side to form a first word line structure and a second word line structure.

12. The method of claim 11, further comprising:
in a fabrication process of forming the initial word line structure, forming an initial back gate structure extending along the second direction, wherein the initial word line structure and the initial back gate structure are disposed on two sides of a row of the semiconductor pillars along a third direction, wherein the third direction is perpendicular to the first direction and the second direction.

13. The method of claim 12, wherein
the initial back gate structure comprises two ends that are opposite in the second direction; and
the part of the initial word line structure removed along the second direction is opposite to the ends in the third direction.

14. The method of claim 12, further comprising:
in a fabrication process of removing the part of the initial first word line structure and the part of the initial second word line structure to form the first word line structure and the second word line structure, removing part of the initial back gate structure from the second side to form a back gate structure.

15. The method of claim 11, wherein removing the part of the initial word line structure along the second direction comprises:
removing a first portion and a second portion of the initial word line structure sequentially along the second direction,
wherein the part of the initial word line structure is spaced between the first portion and the second portion in the second direction.

16. The method of claim 15, further comprising:
in a fabrication process of removing the part of the initial first word line structure and the part of the initial second word line structure to form the first word line structure and the second word line structure, retaining the part of the initial word line structure spaced therebetween, to form a third word line structure.

17. The method of claim 15, wherein the initial word line structure comprises a first conductive layer and a first isolation layer from inside to outside, and removing the part of the initial first word line structure and the part of the initial second word line structure from the second side opposite to the first side to form the first word line structure and the second word line structure comprises:
removing a part of the substrate, a part of the first isolation layer of the initial first word line structure and a part of the first isolation layer of the initial second word line structure from the second side, to expose the first conductive layer of the initial first word line structure and the first conductive layer of the initial second word line structure; and
continuing to remove a part of the first isolation layer of the initial first word line structure and a part of the first isolation layer of the initial second word line structure along the first direction, and removing a part of the first conductive layer of the initial first word line structure and a part of the first conductive layer of the initial second word line structure, to form the first word line structure and the second word line structure,
wherein in the first direction, a lower end face of the first conductive layer of the remaining first word line structure is higher than a lower end face of the first isolation layer of the remaining first word line structure; and
in the first direction, a lower end face of the first conductive layer of the remaining second word line structure is higher than a lower end face of the first isolation layer of the remaining second word line structure.

18. The method of claim 17, further comprising:
after removing the part of the initial word line structure along the second direction, forming an isolation structure in a gap formed after removing the part of the initial word line structure; and
in a fabrication process of continuing to remove a part of the first isolation layer of the initial first word line structure and a part of the first isolation layer of the initial second word line structure, the continuing to remove the part of the first isolation layer of the initial first word line structure and the part of the first isolation layer of the initial second word line structure stops at the isolation structure.

19. The method of claim 11, wherein
a cross-sectional shape of the initial word line structure in a plane perpendicular to the first direction comprises at least one of a rectangular shape, a trapezoidal shape, a circular shape or an oval shape.

20. A memory system, comprising:
a controller, and
a semiconductor device comprising:
a plurality of semiconductor pillars extending along a first direction and each comprising at least one side face, wherein the plurality of semiconductor pillars are arranged in rows along a second direction perpendicular to the first direction; and
a word line structure located between a first row of semiconductor pillars and a second row of semiconductor pillars that are adjacent to each other, and comprising a first word line structure and a second word line structure spaced apart from the first word line structure,
wherein the first word line structure is connected with a side face of the first row of semiconductor pillars; and
the second word line structure is connected with a side face of the second row of semiconductor pillars,
wherein the controller is coupled to the semiconductor device and configured to control the semiconductor device to store data.
